(19) United States
(12) Patent Application Publication
(10) Pub. No.: US 2024/0199854 A1
(43) Pub. Date: Jun. 20, 2024

(54) COMPOSITION, CURED FILM, STRUCTURAL BODY, OPTICAL FILTER, SOLID-STATE IMAGING ELEMENT, IMAGE DISPLAY DEVICE, AND MANUFACTURING METHOD OF CURED FILM

(71) Applicant: FUJIFLIM Corporation, Tokyo (JP)

(72) Inventors: Keiji YAMAMOTO, Haibara-gun (JP); Daisuke KASHIWAGI, Haibara-gun (JP); Takashi KAWASHIMA, Haibara-gun (JP)

(73) Assignee: FUJIFLIM Corporation, Tokyo (JP)

(21) Appl. No.: 18/443,817

(22) Filed: Feb. 16, 2024

Related U.S. Application Data
(63) Continuation of application No. PCT/JP22/31669, filed on Aug. 23, 2022.

(30) Foreign Application Priority Data
Aug. 31, 2021 (JP) 2021-140678
Jul. 22, 2022 (JP) 2022-117094

(51) Int. Cl. C08K 9/06; C08K 3/36; G02B 5/20; G03F 7/075

(52) U.S. Cl. CPC C08K 9/06; C08K 3/36; G03F 7/0752; G02B 5/20

(57) ABSTRACT

Provided are a composition containing particles having a silanol group, at least one generator selected from the group consisting of an acid generator and a base generator, and a solvent, in which a content of the particles having a silanol group in a total solid content of the composition is 43% by mass or more; a cured film formed of the composition; a structural body; an optical filter; a solid-state imaging element; an image display device; and a manufacturing method of a cured film using the composition.

### CROSS-REFERENCE TO RELATED APPLICATIONS

This application is a Continuation of PCT International Application No. PCT/JP2022/031669 filed on Aug. 23, 2022, which claims priority under 35 U.S.C § 119(a) to Japanese Patent Application No. 2021-140678 filed on Aug. 31, 2021, and Japanese Patent Application No. 2022-117094 filed on Jul. 22, 2022. Each of the above application(s) is hereby expressly incorporated by reference, in its entirety, into the present application.

### BACKGROUND OF THE INVENTION

### 1. Field of the Invention

The present invention relates to a composition containing particles. In addition, the present invention relates to a cured film, a structural body, an optical filter, a solid-state imaging element, an image display device, and a manufacturing method of a cured film.

### 2. Description of the Related Art

An optically functional layer such as a low refractive index film is applied to, for example, a surface of a transparent base material in order to prevent reflection of incident light. Application fields of the optically functional layer are wide, and the optically functional layer is applied to products in various fields such as a display device, an optical instrument, a building material, an observation instrument, and a window glass. As a material thereof, various materials, both organic and inorganic, are used and targeted for development. Among these, in recent years, development of materials applied to an optical instrument has been promoted.

For example, an optically functional layer applied to a precision optical instrument such as an image sensor is required to have fine and accurate processability. Therefore, in the related art, a vapor phase method such as a vacuum evaporation method and a sputtering method, which is suitable for fine process, has been adopted. As a material, for example, a single-layer film consisting of MgF₂, cryolite, or the like has been put into practical use. In addition, attempts have also been made to apply a metal oxide such as SiO₂, TiO₂, and ZrO₂.

On the other hand, in the vapor phase method such as a vacuum evaporation method and a sputtering method, since processing equipment and the like are expensive, manufacturing cost may be high. Correspondingly, in recent years, it has been studied to manufacture the optically functional layer such as a low refractive index film using a composition containing inorganic particles such as silica particles.

JP2014-034488A discloses that an antireflection film or the like is produced using a composition containing silica particles having a hollow structure.

### SUMMARY OF THE INVENTION

In recent years, attempts have been made to form a cured film on a member having low heat resistance. For example, in recent years, a display device has been adapted to be an organic electroluminescent (EL) display device. Since an organic semiconductor element such as an organic electroluminescent display element is a member having low heat resistance, in a case where a cured film is formed on such a member having low heat resistance, it is desirable to suppress thermal damage to a support by forming the cured film by a low-temperature process of, for example, 150° C. or less.

However, in a case where the cured film is formed by the low-temperature process, a degree of curing of the cured film may be insufficient, and there is room for improvement in moisture resistance of the cured film. In addition, according to studies of the present inventor, it has been found that there is room for further improvement in the moisture resistance of the cured film even in the composition disclosed in JP2014-034488A.

Accordingly, an object of the present invention is to provide a composition capable of forming a cured film having excellent moisture resistance. Another object of the present invention is to provide a cured film, a structural body, an optical filter, a solid-state imaging element, an image display device, and a manufacturing method of a cured film.

The present invention provides the following.
<1> A composition comprising:
particles having a silanol group;
at least one generator selected from the group consisting of an acid generator and a base generator; and
a solvent,
in which a content of the particles having a silanol group in a total solid content of the composition is 43% by mass or more.
<2> The composition according to <1>,
in which a total content of the particles having a silanol group and the generator in the total solid content of the composition is 45% to 99% by mass.
<3> The composition according to <1> or <2>,
in which the particles having a silanol group are silica particles.
<4> The composition according to <3>,
in which the silica particles include at least one selected from the group consisting of silica particles having a shape in which a plurality of spherical silicas are connected in a bead shape, silica particles having a shape in which a plurality of spherical silicas are connected in a planar shape, and silica particles having a hollow structure.
<5> The composition according to any one of <1> to <4>,
in which the generator is an acid generator, and
the acid generator includes a photoacid generator.
<6> The composition according to <5>,
in which a content of the photoacid generator in the total solid content of the composition is 1% to 10% by mass.
<7> The composition according to <5> or <6>,
in which the photoacid generator includes at least one selected from the group consisting of an oxime sulfonate compound and a triazine compound.
<8> The composition according to any one of <1> to <4>,
in which the generator is a base generator, and
the base generator includes a photobase generator.
<9> The composition according to <8>,
in which a content of the photobase generator in the total solid content of the composition is 1% to 10% by mass.
<10> The composition according to <8> or <9>,
in which the photobase generator includes at least one selected from the group consisting of a carbamate compound and an acyl oxime compound.
<11> The composition according to any one of <1> to <10>, further comprising:
a silanol compound having a molecular weight of 1,000 or less.
<12> The composition according to any one of <1> to <11>, further comprising:
a surfactant.
<13> The composition according to any one of <1> to <12>, further comprising:
a compound having an alkoxysilyl group.
<14> The composition according to any one of <1> to <13>,
in which a content of a resin in the total solid content of the composition is 30% by mass or less.
<15> The composition according to any one of <1> to <14>,
in which the composition is a composition for forming a member adjacent to a pixel of an optical filter having a plurality of pixels.
<16> The composition according to any one of <1> to <15>,
in which the composition is a composition for forming a partition wall.
<17> The composition according to any one of <1> to <16>,
in which, in a case where the composition is applied onto a silicon wafer and heated at 100° C. for 5 minutes to form a film having a thickness of 0.4 μm, a refractive index of the film to light having a wavelength of 633 nm is 1.4 or less.
<18> A cured film formed of the composition according to any one of <1> to <17>.
<19> A structural body comprising:
a support;
a partition wall formed of the composition according to any one of <1> to <17>, which is provided on the support; and
a pixel provided in a region partitioned by the partition wall.
<20> An optical filter comprising:
the cured film according to <18>.
<21> A solid-state imaging element comprising:
the cured film according to <18>.
<22> An image display device comprising:
the cured film according to <18>.
<23> A manufacturing method of a cured film, comprising:
a step of applying the composition according to any one of <1> to <17> onto a support to form a composition layer; and
a step of subjecting the composition layer to a curing treatment,
in which a cured film in which the composition layer is cured is obtained at a temperature of 150° C. or lower throughout all the steps, and
the step of subjecting the composition layer to a curing treatment includes a step of generating an acid or a base from an acid generator or a base generator contained in the composition layer by performing light irradiation or heating on the composition layer.

According to the present invention, it is possible to provide a composition capable of forming a cured film having excellent moisture resistance. In addition, according to the present invention, it is possible to provide a cured film, a structural body, an optical filter, a solid-state imaging element, an image display device, and a manufacturing method of a cured film.

### BRIEF DESCRIPTION OF THE DRAWINGS

FIG. 1 is an enlarged view schematically showing silica particles having a shape in which a plurality of spherical silicas are connected in a bead shape.

FIG. 2 is a side-sectional view showing an embodiment of a structural body according to the present invention.

FIG. 3 is a plan view of the structural body as viewed from directly above a support.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, the term “step” denotes not only an individual step but also a step which is not clearly distinguishable from another step as long as an effect expected from the step can be achieved.

### <Composition>

The composition according to the embodiment of the present invention is a composition containing
particles having a silanol group;
at least one generator selected from the group consisting of an acid generator and a base generator; and
a solvent,
in which a content of the particles having a silanol group in a total solid content of the composition is 43% by mass or more.

With the composition according to the embodiment of the present invention, a cured film having excellent moisture resistance can be formed. Particularly, even in a case where a cured film is formed at a low temperature of 150° C. or lower (preferably 120° C. or lower), a cured film having excellent moisture resistance can be formed.

The detailed reason for obtaining such an effect is not sure, but is presumed as follows. Since the composition according to the embodiment of the present invention contains at least one generator selected from the group consisting of an acid generator and a base generator, it is presumed that, in a case where a cured film is formed of the composition according to the embodiment of the present invention, an acid or a base is generated from the generator by applying energy such as light or heat, and a dehydration condensation reaction of the particles having a silanol group can be promoted by the generated acid or base. In the composition according to the embodiment of the present invention, since the content of the particles having a silanol group in the total solid content of the composition is 43% by mass or more, it is presumed that a proportion of the silanol group in the composition is high, and the dehydration condensation reaction of the particles having a silanol group is more easily promoted. For this reason, it is presumed that the composition according to the embodiment of the present invention is capable of forming a cured film having excellent moisture resistance.

A viscosity of the composition according to the embodiment of the present invention at 25° C. is preferably 3.6 mPa·s or less, more preferably 3.4 mPa·s or less, and still more preferably 3.2 mPa·s or less. In addition, the lower limit is preferably 1.0 mPa·s or more, more preferably 1.4 mPa·s or more, and still more preferably 1.8 mPa·s or more.

A concentration of solid contents of the composition according to the embodiment of the present invention is preferably 5% by mass or more, more preferably 7% by mass or more, and still more preferably 8% by mass or more. The upper limit is preferably 15% by mass or less, more preferably 12% by mass or less, and still more preferably 10% by mass or less.

A surface tension of the composition according to the embodiment of the present invention at 25° C. is preferably 27.0 mN/m or less, more preferably 26.0 mN/m or less, still more preferably 25.5 mN/m or less, and even more preferably 25.0 mN/m or less. The lower limit is preferably 20.0 mN/m or more, more preferably 21.0 mN/m or more, and still more preferably 22.0 mN/m or more.

In a case where the composition according to the embodiment of the present invention is applied to a glass substrate and heated at 100° C. for 5 minutes to form a film having a thickness of 0.4 μm, from the viewpoint of stability of the composition, the contact angle of the film with water at 25° C. is preferably 20° or more, more preferably 25° or more, and still more preferably 30° or more. From the viewpoint of application properties of the composition, the upper limit is preferably 70° or less, more preferably 65° or less, and still more preferably 60° or less. The contact angle is a value measured using a contact angle meter (DM-701, manufactured by Kyowa Interface Science Co., Ltd.).

In a case where the composition according to the embodiment of the present invention is applied onto a silicon wafer and heated at 100° C. for 5 minutes to form a film having a thickness of 0.4 μm, a refractive index of the film to light having a wavelength of 633 nm is preferably 1.45 or less, more preferably 1.4 or less, still more preferably 1.35 or less, even more preferably 1.3 or less, and even still more preferably 1.27 or less. The lower limit is not particularly limited, but can be 1.15 or more. The above-described refractive index is a value measured using an ellipsometer (manufactured by J.A. Woollam, VUV-vase [trade name]). The measurement temperature is 25° C.

The composition according to the embodiment of the present invention can be used for an optically functional layer or the like in an image display device or a solid-state imaging element. Examples of the optically functional layer include an antireflection layer, a layer of low refractive index, and a waveguide.

In addition, the composition according to the embodiment of the present invention can be used as a composition for forming a member adjacent to a pixel of an optical filter having a plurality of pixels. Examples of such a member include a partition wall for separating pixels of an optical filter from each other. That is, the composition according to the embodiment of the present invention can be preferably used as a composition for forming a partition wall. Examples of the pixel partitioned by the partition wall include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel.

In addition, the above-described member may be used by being disposed on a light incidence side or a light emission side of an optical filter.

In the present specification, a case where a member is adjacent to a pixel is not limited to a case where the member is in contact with the pixel, and includes a case where another layer is interposed between the member and the pixel.

In addition, a cured film may be formed on a microlens of a solid-state imaging element having a microlens or an image display device, using the composition according to the embodiment of the present invention.

Hereinafter, each of the components used in the composition according to the embodiment of the present invention will be described.

### <<Particles Having Silanol Group>>

The composition according to the embodiment of the present invention contains particles having a silanol group (hereinafter, also referred to as specific particles).

It is preferable that the specific particles are particles which are not easily dissolved in water.

As one form of the specific particles, silica particles are exemplified.

In addition, as another form of the specific particles, surface-treated particles obtained by surface-treating inorganic particles or resin particles with a silanol compound are exemplified. Examples of the surface treatment method using a silanol compound include a sol-gel method and a silane coupling treatment. In a case of the surface-treated particles, the total mass of the inorganic particles or resin particles as an object to be treated with the silanol compound and the silanol compound adhering to a surface of the object to be treated is the mass of the particles having a silanol group.

Examples of the above-described inorganic particles include titanium oxide particles, strontium titanate particles, barium titanate particles, zinc oxide particles, magnesium oxide particles, zirconium oxide particles, aluminum oxide particles, barium sulfate particles, aluminum hydroxide particles, calcium silicate particles, aluminum silicate particles, and zinc sulfide particles. Examples of the resin particles include (meth)acrylic resin particles, epoxy resin particles, polycarbonate resin particles, polyether resin particles, polyimide resin particles, polyamide resin particles, polyolefin resin particles, cyclic olefin resin particles, polyester resin particles, styrene resin particles, fluororesin particles, and siloxane resin particles. Examples of the silanol compound used for the surface treatment include monosilanol compounds such as trimethylsilanol, triethylsilanol, phenyldimethylsilanol, diphenylmethylsilanol, triphenylsilanol, and dihydroxydiphenylsilane (diphenyldisilanol).

A content of the silanol compound in the surface-treated particles is preferably 0.1% to 30% by mass. The lower limit is preferably 1% by mass or more and more preferably 5% by mass or more. The upper limit is preferably 20% by mass or less and more preferably 15% by mass or less.

The specific particles are preferably silica particles because a cured film having excellent moisture resistance and a low refractive index is easily formed.

Examples of the silica particles include silica particles having a shape in which a plurality of spherical silicas are connected in a bead shape, silica particles having a shape in which a plurality of spherical silicas are connected in a planar shape, silica particles having a hollow structure, and solid silica particles.

From the reason that a cured film having more excellent moisture resistance and lower refractive index is easily formed, the silica particles are preferably at least one selected from the group consisting of silica particles having a shape in which a plurality of spherical silicas are connected in a bead shape, silica particles having a shape in which a plurality of spherical silicas are connected in a planar shape, and silica particles having a hollow structure; and more preferably silica particles having a shape in which a plurality of spherical silicas are connected in a bead shape or silica particles having a shape in which a plurality of spherical silicas are connected in a planar shape.

Hereinafter, the silica particles having a shape in which a plurality of spherical silicas are connected in a bead shape and the silica particles having a shape in which a plurality of spherical silicas are connected in a planar shape are collectively referred to as beaded silica. The silica particles having a shape in which a plurality of spherical silicas are connected in a bead shape may have a shape in which a plurality of spherical silicas are connected in a planar shape.

In addition, the silica particles having a hollow structure are silica particles having a cavity inside the particles. Hereinafter, the silica particles having a hollow structure are also referred to as hollow silica.

In addition, the solid silica particles refer to silica particles having a structure which does not have a cavity therein.

In addition, the silica particles are also preferably silica particles in which a part of silanol groups on the surface of the silica particles is treated with a hydrophobizing treatment agent which reacts with the silanol group. As the hydrophobizing treatment agent, a compound having a structure which reacts with the silanol group on the surface of the silica particles (preferably, a structure which reacts with the silanol group on the surface of the silica particles by coupling) so as to improve hydrophobicity of the silica particles is used. The hydrophobizing treatment agent is preferably an organic compound. Specific examples of the hydrophobizing treatment agent include an organosilane compound, an organotitanium compound, an organozirconium compound, and an organoaluminum compound, and from the reason that increase in refractive index can be suppressed, an organosilane compound is more preferable. In a case where the surfaces of the silica particles are treated with a surface treatment agent such as the hydrophobizing treatment agent, the total mass of the silica particles and the surface treatment agent attached to the silica particles is the mass of the particles having a silanol group.

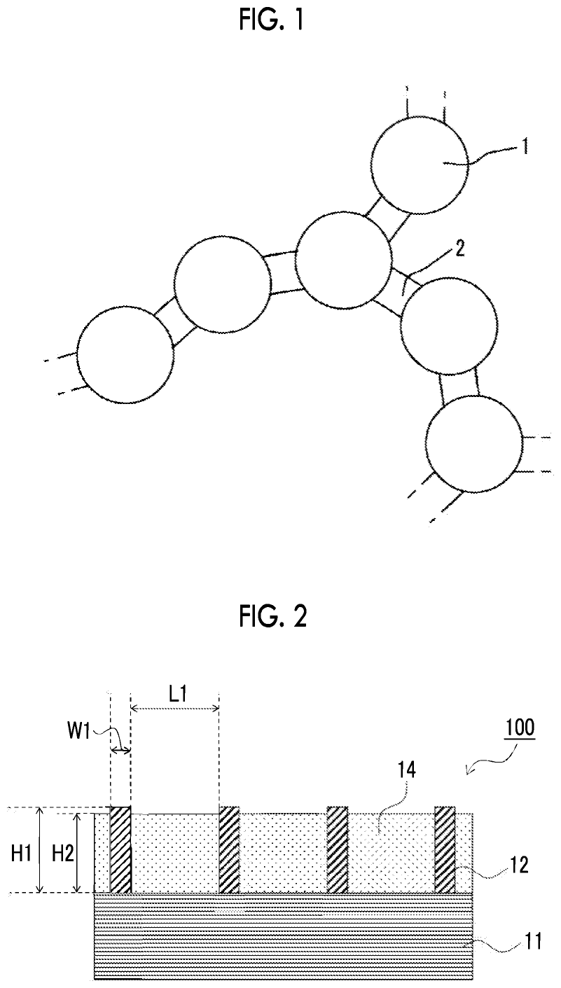

In the present specification, the “spherical” in the “spherical silica” means that the particle may be substantially spherical and may be deformed within a range in which the effect of the present invention is exhibited. For example, the “spherical” is meant to include a shape having roughness on the surface, and a flat surface having a long axis in a predetermined direction. In addition, the “a plurality of spherical silicas are connected in a bead shape” means a structure in which a plurality of spherical silicas are connected to each other in a linear and/or branched form. Examples thereof include a structure in which a plurality of spherical silicas 1 are connected by a connection portion 2 having a smaller outer diameter, as shown in FIG. 1. In addition, in the present invention, the structure in which “a plurality of spherical silicas are connected in a bead shape” includes not only a ring-shaped structure, but also a chain-shaped structure with ends. In addition, the “a plurality of spherical silicas are connected in a planar shape” means a structure in which a plurality of spherical silicas are connected to each other on substantially the same plane. The “substantially the same plane” means not only a case where the plurality of spherical silicas have the same plane, but also a case where the plurality of spherical silicas may be vertically displaced from the same plane. For example, the plurality of spherical silicas may be displaced up and down within a range of 50% or less of a particle diameter of the spherical silica.

In the beaded silica, a ratio D₁/D₂ of an average particle diameter D₁ measured by a dynamic light scattering method and an average particle diameter D₂ obtained by the following expression (1) is preferably 3 or more. The upper limit of D₁/D₂ is not particularly limited, but is preferably 1000 or less, more preferably 800 or less, and still more preferably 500 or less. By setting D₁/D₂ within such a range, good optical characteristics can be exhibited. The value of D₁/D₂ in the beaded silica is also an indicator of a degree of connection of the spherical silica.

D₂=2720/S (1)

In the expression, D₂ is an average particle diameter of the beaded silica, in units of nm, and S is a specific surface area of the beaded silica measured by a nitrogen adsorption process, in units of m²/g.

The above-described average particle diameter D₂ of the beaded silica can be regarded as an average particle diameter close to a diameter of primary particles of the spherical silica. The average particle diameter D₂ is preferably 1 nm or more, more preferably 3 nm or more, still more preferably 5 nm or more, and particularly preferably 7 nm or more. The upper limit is preferably 100 nm or less, more preferably 80 nm or less, still more preferably 70 nm or less, even more preferably 60 nm or less, and particularly preferably 50 nm or less.

The average particle diameter D₂ can be replaced by a circle-equivalent diameter (D0) in a projection image of the spherical portion measured by a transmission electron microscope (TEM). Unless otherwise specified, the average particle diameter based on the circle-equivalent diameter is evaluated by the number average of 50 or more particles.

The above-described average particle diameter D₁ of the beaded silica can be regarded as a number average particle diameter of secondary particles in which a plurality of spherical silicas are collected. Therefore, a relationship of D₁>D₂ is usually satisfied. The average particle diameter D₁ is preferably 5 nm or more, more preferably 7 nm or more, and particularly preferably 10 nm or more. The upper limit is preferably 100 nm or less, more preferably 70 nm or less, still more preferably 50 nm or less, and particularly preferably 45 nm or less.

Unless otherwise specified, the above-described average particle diameter D₁ of the beaded silica is measured using a dynamic light scattering type particle size distribution measuring device (Microtrac UPA-EX150, manufactured by Nikkiso Co., Ltd.). The procedure is as follows. A dispersion liquid of the beaded silica is divided into 20 ml sample bottles, and diluted with propylene glycol monomethyl ether so that the concentration of solid contents is 0.2% by mass. The diluted sample solution is irradiated with 40 kHz ultrasonic waves for 1 minute, and immediately after that, the sample solution is used for test. Data is captured 10 times using a 2 ml quartz cell for measurement at a temperature of 25° C., and the obtained “number average” is regarded as the average particle diameter. For other detailed conditions and the like, the description of “Particle size analysis—Dynamic light scattering method” in JIS Z8828:2013 can be referred to as necessary. Five samples are produced for each level and the average value thereof is adopted.

As the beaded silica, it is preferable that a plurality of spherical silicas having an average particle diameter of 1 to 80 nm are connected through a connecting material. The upper limit of the average particle diameter of the spherical silica is preferably 70 nm or less, more preferably 60 nm or less, and still more preferably 50 nm or less. In addition, the lower limit of the average particle diameter of the spherical silica is preferably 3 nm or more, more preferably 5 nm or more, and still more preferably 7 nm or more. In the present invention, as the value of the average particle diameter of the spherical silica, a value of an average particle diameter obtained from the circle-equivalent diameter in the projection image of the spherical portion measured by a transmission electron microscope (TEM) is used.

In the beaded silica, examples of the connecting material for connecting the spherical silicas include metal oxide-containing silica. Examples of the metal oxide include an oxide of metal selected from Ca, Mg, Sr, Ba, Zn, Sn, Pb, Ni, Co, Fe, Al, In, Y, and Ti. Examples of the metal oxide-containing silica include a reactant and a mixture of these metal oxides and silica (SiO₂). With regard to the connecting material, reference can be made to the description in WO2000/015552A, the content of which is incorporated herein by reference.

The number of connected spherical silicas in the beaded silica is preferably 3 or more and more preferably 5 or more. The upper limit is preferably 1000 or less, more preferably 800 or less, and still more preferably 500 or less. The number of connected spherical silicas can be measured by TEM.

Examples of a commercially available product of a particle solution containing the beaded silica include SNOWTEX series and ORGANOSILICASOL series (methanol dispersion liquid, isopropyl alcohol dispersion liquid, ethylene glycol dispersion liquid, methyl ethyl ketone dispersion liquid, and the like;

product numbers: IPA-ST-UP, MEK-ST-UP, and the like) manufactured by Nissan Chemical Corporation. In addition, as the particle solution containing the beaded silica, for example, a silica sol described in JP4328935B can be used.

An average particle diameter of the hollow silica is preferably 10 to 500 nm. The lower limit is preferably 15 nm or more, more preferably 20 nm or more, and still more preferably 25 nm or more. The upper limit is preferably 300 nm or less, more preferably 200 nm or less, and still more preferably 100 nm or less. The average particle diameter of the hollow silica is a value measured by a dynamic light scattering method. Examples of a commercially available product of a particle solution including the hollow silica include THRULYA 4110 manufactured by JGC C&C.

An average particle diameter of the solid silica particles is preferably 5 to 500 nm. The lower limit is preferably 10 nm or more. The upper limit is preferably 300 nm or less, more preferably 200 nm or less, and still more preferably 100 nm or less. The average particle diameter of the solid silica particles is a value measured by a dynamic light scattering method. Examples of a commercially available product of a particle solution containing the solid silica particles include MIBK-ST manufactured by Nissan Chemical Corporation.

The content of the specific particles in the total solid content of the composition is 43% by mass or more, preferably 50% by mass or more, more preferably 60% by mass or more, still more preferably 70% by mass or more, even more preferably 80% by mass or more, and particularly preferably 90% by mass or more. The upper limit is preferably 99% by mass or less, more preferably 98% by mass or less, and still more preferably 95% by mass or less.

In addition, the content of the specific particles in the composition is preferably 3% by mass or more, more preferably 5% by mass or more, and still more preferably 7% by mass or more. The upper limit is preferably 30% by mass or less, more preferably 20% by mass or less, and still more preferably 15% by mass or less.

In a case where the silica particles are used as the specific particles, a content of the specific particles in the total solid content of the composition is preferably 43% by mass or more, more preferably 50% by mass or more, still more preferably 60% by mass or more, even more preferably 70% by mass or more, even still more preferably 80% by mass or more, and particularly preferably 90% by mass or more. The upper limit is preferably 99% by mass or less, more preferably 98% by mass or less, and still more preferably 95% by mass or less.

In addition, the content of the silica particles in the composition is preferably 3% by mass or more, more preferably 5% by mass or more, and still more preferably 7% by mass or more. The upper limit is preferably 30% by mass or less, more preferably 20% by mass or less, and still more preferably 15% by mass or less.

In a case where the content of the silica particles is within the above-described range, it is easy to obtain a cured film having a low refractive index, a high antireflection effect, and excellent moisture resistance.

In addition, from the reason that it is easy to obtain a cured film having a low refractive index, a high antireflection effect, and excellent moisture resistance, the content of the silica particles in the total amount of particles contained in the composition is preferably 80% by mass or more, more preferably 90% by mass or more, and still more preferably 95% by mass or more. The particles contained in the composition are preferably substantially only the silica particles. The case where the particles contained in the composition are substantially only the silica particles means that the content of the silica particles in the total amount of the particles is 99% by mass or more, more preferably 99.9% by mass or more, and still more preferably 100% by mass.

### <<Generator>>

The composition according to the embodiment of the present invention contains at least one generator selected from the group consisting of an acid generator and a base generator. It is preferable that the generator is substantially only an acid generator or substantially only a base generator, and from the viewpoint of suppressing damage to the film, corrosion of metal members, and the like, it is preferable that the generator is substantially only a base generator.

In the present specification, the case where the generator is substantially only an acid generator means that a content of the acid generator is 99% by mass or more, preferably 99.9% by mass or more and more preferably 100% by mass (consisting of only an acid generator), with respect to the total mass of the generator. In addition, the case where the generator is substantially only a base generator means that a content of the base generator is 99% by mass or more, preferably 99.9% by mass or more and more preferably 100% by mass (consisting of only a base generator), with respect to the total mass of the generator.

### (Acid Generator)

Examples of the acid generator include a thermal acid generator and a photoacid generator. It is preferable that the acid generator includes a photoacid generator. In addition, as the acid generator, a photoacid generator and a thermal acid generator may be used in combination. In a case where the thermal acid generator and the photoacid generator are used in combination, a mass ratio of the thermal acid generator and the photoacid generator is preferably 100 to 2000 parts by mass of the photoacid generator with respect to 100 parts by mass of the thermal acid generator. The lower limit is preferably 150 parts by mass or more and more preferably 200 parts by mass or more. The upper limit is preferably 1500 parts by mass or less and more preferably 1000 parts by mass or less. Among these, from the reason that the process temperature can be lowered and a film having excellent moisture resistance can be formed, it is particularly preferable that the acid generator is substantially only a photoacid generator. In the present specification, the case where the acid generator is substantially only a photoacid generator means that a content of the photoacid generator is 99% by mass or more, preferably 99.9% by mass or more and more preferably 100% by mass (consisting of only a photoacid generator), with respect to the total mass of the acid generator.

In the present specification, the acid generator means a compound which generates an acid by applying energy such as heat or light. In addition, the thermal acid generator means a compound which generates an acid by thermal decomposition. In addition, the photoacid generator means a compound which generates an acid upon irradiation with light.

The acid generator may be an ionic acid generator or a non-ionic acid generator, but is preferably a non-ionic acid generator. In a case where a non-ionic acid generator is used as the acid generator, in a case where the composition according to the embodiment of the present invention is used in a solid-state imaging element or an image display device, it is possible to reduce operation failure due to ion impurities in these devices.

The acid generator is preferably a compound which generates an acid having a pKa of 4 or less, more preferably a compound which generates an acid having a pKa of 3 or less, and still more preferably a compound which generates an acid having a pKa of 2 or less. According to this aspect, a cured film having more excellent moisture resistance is easily formed. In the present specification, pKa basically refers to pKa in water at 25° C. With a compound which cannot be measured in water, the pKa refers to a pKa measured after changing to a solvent suitable for the measurement. Specifically, pKa described in a chemical handbook or the like can be referred to. As the acid having a pKa of 3 or less, a sulfonic acid or a phosphonic acid is preferable, and a sulfonic acid is more preferable.

A molecular weight of the acid generator is preferably 200 to 1,000. The lower limit is preferably 230 or more. The upper limit is preferably 800 or less. In a case where the molecular weight of the acid generator is within the above-described range, the acid generator can be easily volatilized during baking or the like in a case of manufacturing the cured film, and the acid generator or a decomposition product thereof can be suppressed from remaining in the film.

### —Thermal Acid Generator—

An acid-generating temperature of the thermal acid generator is preferably 80° C. to 130° C. and more preferably 90° C. to 110° C.

The thermal acid generator is preferably a compound which generates a weakly nucleophilic acid such as a sulfonic acid, a carboxylic acid, and a disulfonylimide, by heating. As the acid generated from the thermal acid generator, an acid having a pKa of 4 or less is preferable, an acid having a pKa of 3 or less is more preferable, and an acid having a pKa of 2 or less is still more preferable. For example, sulfonic acid, an alkylcarboxylic acid or an arylcarboxylic acid, which is substituted with an electron-withdrawing group, disulfonylimide, or the like is preferable. Examples of the electron-withdrawing group include a halogen atom such as a fluorine atom, a haloalkyl group such as a trifluoromethyl group, a nitro group, and a cyano group.

Examples of the thermal acid generator include a diazomethane compound, a sulfonic acid ester compound, a carboxylic acid ester compound, a phosphoric acid ester compound, a sulfonimide compound, a sulfonbenzotriazole compound, and a sulfonium salt; and a sulfonic acid ester compound or a sulfonimide compound is preferable.

In addition, it is also preferable that the thermal acid generator is a sulfonic acid ester compound which does not substantially generate an acid upon irradiation with actinic rays or radiation and generates an acid by heat. The fact that an acid is not substantially generated by irradiation with actinic rays or radiation can be determined by measuring an infrared absorption (IR) spectrum and a nuclear magnetic resonance (NMR) spectrum of the compound before and after the exposure, and observing that there is no change in the spectrums. A molecular weight of the above-described sulfonic acid ester compound is preferably 230 to 1,000 and more preferably 230 to 800.

Examples of the sulfonic acid ester compound include tetraethylene glycol bis(p-toluenesulfonate), butyl p-toluenesulfonate, 4-hydroxyphenyldimethylsulfonium trifluoromethanesulfonate, benzyl-4-hydroxyphenylmethylsulfonium trifluoromethanesulfonate, 2-methylbenzyl-4-hydroxyphenylmethylsulfonium trifluoromethanesulfonate, 4-acetoxyphenyldimethylsulfonium trifluoromethanesulfonate, 4-acetoxyphenylbenzylmethylsulfonium trifluoromethanesulfonate, 4-(methoxycarbonyloxy)phenyldimethylsulfonium trifluoromethanesulfonate, and benzyl-4-(methoxycarbonyloxy)phenylmethylsulfonium trifluoromethanesulfonate.

Examples of the sulfonimide compound include N-(trifluoromethylsulfonyloxy)succinimide (trade name “SI-105”, Midori Kagaku Co., Ltd.), N-(camphorsulfonyloxy)succinimide (trade name “SI-106”, Midori Kagaku Co., Ltd.), N-(4-methylphenylsulfonyloxy)succinimide (trade name “SI-101”, Midori Kagaku Co., Ltd.), N-(2-trifluoromethylphenylsulfonyloxy)succinimide, N-(4-fluorophenylsulfonyloxy)succinimide, N-(trifluoromethylsulfonyloxy)phthalimide, N-(camphorsulfonyloxy)phthalimide, N-(2-trifluoromethylphenylsulfonyloxy)phthalimide, N-(2-fluorophenylsulfonyloxy)phthalimide, N-(trifluoromethylsulfonyloxy)diphenylmaleimide (trade name “PI-105”, Midori Kagaku Co., Ltd.), N-(camphorsulfonyloxy)diphenylmaleimide, 4-(methylphenylsulfonyloxy)diphenylmaleimide, N-(2-trifluoromethylphenylsulfonyloxy)diphenylmaleimide, N-(4-fluorophenylsulfonyloxy)diphenylmaleimide, N-(4-fluorophenylsulfonyloxy)diphenylmaleimide, N-(phenylsulfonyloxy)bicyclo[2.2.1]hept-5-ene-2,3-dicarboxylimide (trade name “NDI-100”, Midori Kagaku Co., Ltd.), N-(4-methylphenylsulfonyloxy)bicyclo[2.2.1]hept-5-ene-2,3-dicarboxylimide (trade name “NDI-101”, Midori Kagaku Co., Ltd.), N-(trifluoromethanesulfonyloxy)bicyclo[2.2.1]hept-5-ene-2,3-dicarboxylimide (trade name “NDI-105”, Midori Kagaku Co., Ltd.), N-(nonafluorobutanesulfonyloxy)bicyclo[2.2.1]hept-5-ene-2,3-dicarboxylimide (trade name “NDI-109”, Midori Kagaku Co., Ltd.), N-(camphorsulfonyloxy)bicyclo[2.2.1]hept-5-ene-2,3-dicarboxylimide (trade name “NDI-106”, Midori Kagaku Co., Ltd.), N-(camphorsulfonyloxy)-7-oxabicyclo[2.2.1]hept-5-ene-2,3-dicarboxylimide, N-(trifluoromethylsulfonyloxy)-7-oxabicyclo[2.2.1]hept-5-ene-2,3-dicarboxylimide, N-(4-methylphenylsulfonyloxy)bicyclo[2.2.1]hept-5-ene-2,3-dicarboxylimide, N-(4-methylphenylsulfonyloxy)-7-oxabicyclo[2.2.1]hept-5-ene-2,3-dicarboxylimide, N-(2-trifluoromethylphenylsulfonyloxy)bicyclo[2.2.1]hept-5-ene-2,3-dicarboxylimide, N-(2-trifluoromethylphenylsulfonyloxy)-7-oxabicyclo[2.2.1]hept-5-ene-2,3-dicarboxylimide, N-(4-fluorophenylsulfonyloxy)bicyclo[2.2.1]hept-5-ene-2,3-dicarboxylimide, N-(4-fluorophenylsulfonyloxy)-7-oxabicyclo[2.2.1]hept-5-ene-2,3-dicarboxylimide, N-(trifluoromethylsulfonyloxy)bicyclo [2.2.1]heptane-5,6-oxy-2,3-dicarboxylimide, N-(camphorsulfonyloxy)bicyclo[2.2.1]heptane-5,6-oxy-2,3-dicarboxylimide, N-(4-methylphenylsulfonyloxy)bicyclo[2.2.1]heptane-5,6-oxy-2,3-dicarboxylimide, N-(2-trifluoromethylphenylsulfonyloxy)bicyclo[2.2.1]heptane-5,6-oxy-2,3-dicarboxylimide, N-(4-fluorophenylsulfonyloxy)bicyclo[2.2.1]heptane-5,6-oxy-2,3-dicarboxylimide, N-(trifluoromethylsulfonyloxy)naphthyldicarboxylimide (trade name “NAI-105”, Midori Kagaku Co., Ltd.), N-(camphorsulfonyloxy)naphthyldicarboxylimide (trade name “NAI-106”, Midori Kagaku Co., Ltd.), N-(4-methylphenylsulfonyloxy)naphthyldicarboxylimide (product name “NAI-101”, Midori Kagaku Co., Ltd.), N-(phenylsulfonyloxy)naphthyldicarboxylimide (product name “NAI-100”, Midori Kagaku Co., Ltd.), N-(2-trifluoromethylphenylsulfonyloxy)naphthyldicarboxylimide, N-(4-fluorophenylsulfonyloxy)naphthyldicarboxylimide, N-(pentafluoroethylsulfonyloxy)naphthyldicarboxylimide, N-(heptafluoropropylsulfonyloxy)naphthyldicarboxylimide, N-(nonafluorobutylsulfonyloxy)naphthyldicarboxylimide (trade name “NAI-109”, Midori Kagaku Co., Ltd.), N-(ethylsulfonyloxy)naphthyldicarboxylimide, N-(propylsulfonyloxy)naphthyldicarboxylimide, N-(butylsulfonyloxy)naphthyldicarboxylimide (trade name “NAI-1004”, Midori Kagaku Co., Ltd.), N-(pentylsulfonyloxy)naphthyldicarboxylimide, N-(hexylsulfonyloxy)naphthyldicarboxylimide, N-(heptylsulfonyloxy)naphthyldicarboxylimide, N-(octylsulfonyloxy)naphthyldicarboxylimide, and N-(nonylsulfonyloxy)naphthyldicarboxylimide.

Examples of a commercially available product of the thermal acid generator include SAN-AID series (for example, SI-60, SI-80, SI-100, SI-200, SI-110, SI-145, SI-150, SI-60L, SI-80L, SI-100L, SI-110L, SI-145L, SI-150L, SI-160L, SI-180L, and the like) manufactured by SANSHIN CHEMICAL INDUSTRY CO., LTD.; TA-100 series manufactured by San-Apro Ltd.; and IK series manufactured by San-Apro Ltd.

### —Photoacid Generator—

The photoacid generator is preferably a compound which is sensitive to actinic rays having a wavelength of 300 nm or more, preferably 300 to 450 nm, and generates an acid. The photoacid generator is preferably a compound which generates an acid having a pKa of 4 or less upon irradiation with light, more preferably a compound which generates an acid having a pKa of 3 or less upon irradiation with light, and still more preferably a compound which generates an acid having a pKa of 2 or less upon irradiation with light. In addition, the photoacid generator is preferably a compound which does not generate an acid at 130° C. or lower.

Examples of the photoacid generator include an oxime sulfonate compound, a triazine compound, a sulfonium salt, an iodonium salt, a quaternary ammonium salt, a diazomethane compound, a sulfone compound, a sulfonic acid ester compound, an iminosulfonic acid ester compound, a carboxylic acid ester compound, and a sulfonimide compound; and from the viewpoint of acid generation efficiency upon exposure and solubility, at least one selected from the group consisting of an oxime sulfonate compound and a triazine compound is preferable.

The oxime sulfonate compound is preferably a compound containing an oxime sulfonate structure represented by Formula (B1-1).

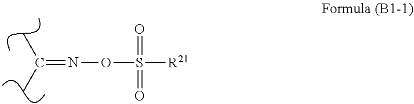

R²¹ in Formula (B1-1) represents an alkyl group or an aryl group. A wave line represents a bond to another group.

The alkyl group represented by R²¹ is preferably a linear or branched alkyl group having 1 to 10 carbon atoms.

As the aryl group represented by R²¹, an aryl group having 6 to 11 carbon atoms is preferable, and a phenyl group or a naphthyl group is more preferable. The aryl group of R²¹ may be substituted with a fluorine atom, an alkyl group, an alkoxy group, or a halogen atom.

The alkyl group and the aryl group represented by R²¹ may have a substituent. Examples of the substituent include a halogen atom, an aryl group having 6 to 11 carbon atoms, an alkoxy group having 1 to 10 carbon atoms, and a cyclic alkyl group (including a bridged alicyclic group such as a 7,7-dimethyl-2-oxonorbornyl group, and preferably a bicycloalkyl group). Examples of the halogen atom include a fluorine atom, a chlorine atom, a bromine atom, and an iodine atom, and a fluorine atom is preferable.

Examples of the compound containing an oxime sulfonate structure represented by Formula (B1-1) include oxime sulfonate compounds described in paragraphs 0081 to 0108 of JP2013-210616A, the content of which is incorporated herein by reference.

Specific examples of the oxime sulfonate compound include compounds having structures described in Examples later.

Examples of the triazine compound include compounds having structures described in Examples later, 2-(3-chlorophenyl)-bis(4,6-trichloromethyl)-s-triazine, 2-(4-methoxyphenyl)-bis(4,6-trichloromethyl)-s-triazine, 2-(4-methylthiophenyl)-bis(4,6-trichloromethyl)-s-triazine, 2-(4-methoxy-β-styryl)-bis(4,6-trichloromethyl)-s-triazine, 2-piperonyl-bis(4,6-trichloromethyl)-s-triazine, 2-[2-(furan-2-yl)ethenyl]-bis(4,6-trichloromethyl)-s-triazine, 2-[2-(5-methylfuran-2-yl)ethenyl]-bis(4,6-trichloromethyl)-s-triazine, 2-[2-(4-diethylamino-2-methylphenyl)ethenyl]-bis(4,6-trichloromethyl)-s-triazine, and 2-(4-methoxynaphthyl)-bis(4,6-trichloromethyl)-s-triazine.

Examples of the iodonium salt include diphenyliodonium trifluoroacetate, diphenyliodonium trifluoromethanesulfonate, 4-methoxyphenylphenyliodonium trifluoromethanesulfonate, 4-methoxyphenylphenyliodonium trifluoroacetate, phenyl-4-(2′-hydroxy-1′-tetradecaoxy)phenyliodonium trifluoromethanesulfonate, 4-(2′-hydroxy-1′-tetradecaoxy)phenyliodonium hexafluoroantimonate, and phenyl-4-(2′-hydroxy-1′-tetradecaoxy)phenyliodonium-p-toluenesulfonate.

Examples of the sulfonium salt include triphenylsulfonium trifluoromethanesulfonate, triphenylsulfonium trifluoroacetate, 4-methoxyphenyldiphenylsulfonium trifluoromethanesulfonate, 4-methoxyphenyldiphenylsulfonium trifluoroacetate, 4-phenylthiophenyldiphenylsulfonium trifluoromethanesulfonate, and 4-phenylthiophenyldiphenylsulfonium trifluoroacetate.

Examples of the quaternary ammonium salt include tetramethylammoniumbutyltris(2,6-difluorophenyl)borate, tetramethylammoniumhexyltris(p-chlorophenyl)borate, tetramethylammoniumhexyltris(3-trifluoromethylphenyl)borate, benzyldimethylphenylammonium butyltris(2,6-difluorophenyl)borate, benzyldimethylphenylammoniumhexyltris(p-chlorophenyl)borate, and benzyldimethylphenylammoniumhexyltris(3-trifluoromethylphenyl)borate.

Examples of the diazomethane compound include bis(trifluoromethylsulfonyl)diazomethane, bis(cyclohexylsulfonyl)diazomethane, bis(phenylsulfonyl)diazomethane, bis(4-tolylsulfonyl)diazomethane, bis(2,4-xylylsulfonyl)diazomethane, bis(4-chlorophenylsulfonyl)diazomethane, methylsulfonyl-4-tolylsulfonyldiazomethane, cyclohexylsulfonyl(1,1-dimethylethylsulfonyl)diazomethane, bis(1,1-dimethylethylsulfonyl)diazomethane, and phenylsulfonyl(benzoyl)diazomethane.

Examples of the sulfone compound include a β-ketosulfone compound, a β-sulfonylsulfone compound, and a diaryldisulfone compound. Preferred examples of the sulfone compound include 4-tolylphenacylsulfone, mesitylphenacylsulfone, bis(phenylsulfonyl)methane, and a 4-chlorophenyl-4-tolyldisulfone compound.

Examples of the sulfonic acid ester compound include benzoin-4-tolylsulfonate, pyrogallol tris(methylsulfonate), nitrobenzyl-9,10-diethoxyanthryl-2-sulfonate, and 2,6-(dinitrobenzyl)phenylsulfonate.

Examples of the iminosulfonic acid ester compound include benzylmonooxime-4-tolylsulfonate, benzylmonooxime-4-dodecyl phenylsulfonate, benzylmonooxime hexadecyl sulfonate, 4-nitroacetophenone oxime-4-tolylsulfonate, 4,4′-dimethylbenzylmonoxime-4-tolylsulfonate, 4,4′-dimethylbenzylmonoxime-4-dodecylphenylsulfonate, dibenzylketoneoxime-4-tolylsulfonate, ethyl α-(4-tolyloxy)imino-α-cyanoacetate, furylmonoxime-4-(aminocarbonyl)phenylsulfonate, acetone oxime-4-benzoylphenylsulfonate, 3-(benzylsulfonyloxy)iminoacetylacetone, bis(benzylmonooxide)dioctylnaphthyl disulfonate, α-(4-tolylsulfonyloxy)iminobenzyl cyanide, α-(4-tolylsulfonyloxy)imino-4-methoxybenzyl cyanide (“PAI-101”, trade name, manufactured by Midori Kagaku Co., Ltd.), α-(10-camphorsulfonyloxy)imino-4-methoxybenzyl cyanide (“PAI-106”, trade name, manufactured by Midori Kagaku Co., Ltd.), and 5-(4-tolylsulfonyloxy)imino-5H-thiophen-2-ylidene-(2-methylphenyl)acetonitrile (“CGI-1311”, trade name, manufactured by BASF SE).

Examples of the carboxylic acid ester compound include carboxylic acid 2-nitrobenzyl ester.

Examples of the sulfonimide compound include N-(trifluoromethylsulfonyloxy)succinimide, N-(10-camphorsulfonyloxy)succinimide, N-(4-tolylsulfonyloxy)succinimide, N-(2-trifluoromethylphenylsulfonyloxy)succinimide, N-(4-fluorophenylsulfonyloxy)succinimide, N-(trifluoromethylsulfonyloxy)phthalimide, N-(10-camphorsulfonyloxy)phthalimide, N-(2-trifluoromethylphenylsulfonyloxy)phthalimide, N-(2-fluorophenylsulfonyloxy)phthalimide, N-(trifluoromethylsulfonyloxy)diphenylmaleimide, N-(10-camphorsulfonyloxy)diphenylmaleimide, 4-tolylsulfonyloxy)diphenylmaleimide, N-(2-trifluoromethylphenylsulfonyloxy)diphenylmaleimide, N-(4-fluorophenylsulfonyloxy)diphenylmaleimide, N-(4-fluorophenylsulfonyloxy)diphenylmaleimide, N-(trifluoromethylsulfonyloxy)bicyclo[2.2.1]hept-5-ene-2,3-dicarboximide, N-(10-camphorsulfonyloxy)bicyclo[2.2.1]hept-5-ene-2,3-dicarboximide, N-(camphorsulfonyloxy)-7-oxabicyclo[2.2.1]hept-5-ene-2,3-dicarboximide, N-(trifluoromethylsulfonyloxy)-7-oxabicyclo[2.2.1]hept-5-ene-2,3-dicarboximide, N-(4-Tolylsulfonyloxy)bicyclo[2.2.1]hept-5-ene-2,3-dicarboximide, N-(4-tolylsulfonyloxy)-7-oxabicyclo[2.2.1]hept-5-ene-2,3-dicarboximide, N-(2-trifluoromethylphenylsulfonyloxy)bicyclo[2.2.1]hept-5-ene-2,3-dicarboximide, N-(2-trifluoromethylphenylsulfonyloxy)-7-oxabicyclo[2.2.1]hept-5-ene-2,3-dicarboximide, N-(4-fluorophenylsulfonyloxy)bicyclo[2.2.1]hept-5-ene-2,3-dicarboximide, N-(4-fluorophenylsulfonyloxy)-7-oxabicyclo[2.2.1]hept-5-ene-2,3-dicarboximide, N-(trifluoromethylsulfonyloxy)bicyclo[2.2.1]heptane-5,6-oxy-2,3-dicarboximide, N-(10-camphorsulfonyloxy)bicyclo[2.2.1]heptane-5,6-oxy-2,3-dicarboxyimide, N-(4-tolylsulfonyloxy)bicyclo[2.2.1]heptane-5,6-oxy-2,3-dicarboximide, N-(2-trifluoromethylphenylsulfonyloxy)bicyclo[2.2.1]heptane-5,6-oxy-2,3-dicarboximide, N-(4-fluorophenylsulfonyloxy)bicyclo[2.2.1]heptane-5,6-oxy-2,3-dicarboximide, N-(trifluoromethylsulfonyloxy)naphthyldicarboximide, N-(10-camphorsulfonyloxy)naphthyldicarboximide, N-(4-tolylsulfonyloxy)naphthyldicarboximide, N-(2-trifluoromethylphenylsulfonyloxy)naphthyldicarboximide, N-(4-fluorophenylsulfonyloxy)naphthyldicarboximide, N-(pentafluoroethylsulfonyloxy)naphthyldicarboximide, N-(heptafluoropropylsulfonyloxy)naphthyldicarboximide, N-(nonafluorobutylsulfonyloxy)naphthyldicarboximide, N-(ethylsulfonyloxy)naphthyldicarboximide, N-(propylsulfonyloxy)naphthyldicarboximide, N-(butylsulfonyloxy)naphthyldicarboximide, N-(pentylsulfonyloxy)naphthyldicarboximide, N-(hexylsulfonyloxy)naphthyldicarboximide, N-(heptylsulfonyloxy)naphthyldicarboximide, N-(octylsulfonyloxy)naphthyldicarboximide, and N-(nonylsulfonyloxy)naphthyldicarboximide.

### (Base Generator)

Examples of the base generator include a thermal base generator and a photobase generator. It is preferable that the base generator includes a photobase generator. In addition, as the base generator, a photobase generator and a thermal-base generator may be used in combination. In a case where the thermal base generator and the photobase generator are used in combination, a mass ratio of the thermal base generator and the photobase generator is preferably 100 to 2000 parts by mass of the photobase generator with respect to 100 parts by mass of the thermal base generator. The lower limit is preferably 150 parts by mass or more and more preferably 200 parts by mass or more. The upper limit is preferably 1500 parts by mass or less and more preferably 1000 parts by mass or less. Among these, from the reason that the process temperature can be lowered and a film having excellent moisture resistance can be formed, it is particularly preferable that the base generator is substantially only a photobase generator. In the present specification, the case where the base generator is substantially only a photobase generator means that a content of the photobase generator is 99% by mass or more, preferably 99.9% by mass or more and more preferably 100% by mass (consisting of only a photobase generator), with respect to the total mass of the base generator.

In the present specification, the base generator means a compound which generates a base by applying energy such as heat or light. In addition, the thermal base generator means a compound which generates a base by thermal decomposition. In addition, the photobase generator means a compound which generates a base upon irradiation with light.

The base generator may be an ionic base generator or a non-ionic base generator, but is preferably a non-ionic base generator. In a case where a non-ionic base generator is used as the base generator, in a case where the composition according to the embodiment of the present invention is used in a solid-state imaging element or an image display device, it is possible to reduce operation failure due to ion impurities in these devices.

The base generated from the base generator may be any of a primary amine, a secondary amine, or a tertiary amine, but from the viewpoint of pot life stability, a tertiary amine is preferable. In addition, a boiling point of the base generated from the base generator is preferably 80° C. or higher, more preferably 100° C. or higher, and most preferably 140° C. or higher. In addition, a molecular weight of the generated base is preferably 80 to 2,000. The lower limit is more preferably 100 or more. The upper limit is more preferably 500 or less. A value of the molecular weight is a theoretical value obtained from a structural formula.

A molecular weight of the base generator is preferably from 200 to 1,000. The lower limit is preferably 230 or more. The upper limit is preferably 800 or less. In a case where the molecular weight of the base generator is within the above-described range, the base generator can be easily volatilized during baking or the like in a case of manufacturing the cured film, and the base generator or a decomposition product thereof can be suppressed from remaining in the film.

### —Thermal Base Generator—

A base-generating temperature of the thermal base generator is preferably 80° C. to 130° C. and more preferably 90° C. to 110° C.

Examples of the thermal base generator include a carbamoyl oxime compound, a carbamoyl hydroxylamine compound, a carbamic acid compound, a formamide compound, an acetamide compound, a carbamate compound, a benzyl carbamate compound, a nitrobenzyl carbamate compound, a sulfonamide compound, an imidazole compound, an amine imide compound, a pyridine compound, an α-aminoacetophenone compound, a quaternary ammonium salt, a pyridinium salt, an α-lactone ring derivative compound, a phthalimide compound, and an acyloxyimino compound.

In addition, as the thermal base generator, an acidic compound which generates a base in a case of being heated to 40° C. or higher, and an ammonium salt having an anion with a pKa1 of 0 to 4 and an ammonium cation can also be used. Examples of these compounds include compounds described in paragraphs 0045 to 0066 of WO2017/141723A, the content of which is incorporated herein by reference.

In the present specification, the acidic compound is a compound obtained by collecting 1 g of the compound in a vessel, adding 50 mL of a mixed solution of ion exchange water and tetrahydrofuran (at a mass ratio of water/tetrahydrofuran=1/4) thereto, and stirring the mixture at room temperature for 1 hour. In the acidic compound, a value measured in the solution at 20° C. using a pH meter is less than 7.

Examples of a commercially available product of the thermal base generator include U-CAT series (for example, SA1, SA102, SA603, SA810, SA831, SA841, SA851, SA838A, and the like) manufactured by San-Apro Ltd.

### —Photobase Generator—

The photobase generator is preferably a compound which is sensitive to actinic rays having a wavelength of 300 nm or more, preferably 300 to 450 nm, and generates a base.

In addition, the photobase generator is preferably a compound which does not generate a base at 130° C. or lower.

Examples of the photobase generator include a carbamate compound, a sulfonamide compound, and an acyl oxime compound, and at least one selected from the group consisting of a carbamate compound and an acyl oxime compound is preferable.

Examples of the carbamate compound include N-(2-nitrobenzyloxy)carbonyl-N-methylamine, N-(2-nitrobenzyloxy)carbonyl-N-n-propylamine, N-(2-nitrobenzyloxy)carbonyl-N-n-hexylamine, N-(2-nitrobenzyloxy)carbonyl-N-cyclohexylamine, N-(2-nitrobenzyloxy)carbonylaniline, N-(2-nitrobenzyloxy)carbonylpiperidine, N,N′-bis[(2-nitrobenzyloxy)carbonyl]-1,6-hexamethylenediamine, N,N′-bis[(2-nitrobenzyloxy)carbonyl]-1,4-phenylenediamine, N,N′-bis[(2-nitrobenzyloxy)carbonyl]-2,4-tolylenediamine, N,N′-bis[(2-nitrobenzyloxy)carbonyl]-4,4′-diaminodiphenylmethane, N,N′-bis[(2-nitrobenzyloxy)carbonyl]piperazine, N-(2,6-dinitrobenzyloxy)carbonyl-N-methylamine, N-(2,6-dinitrobenzyloxy)carbonyl-N-n-propylamine, N-(2,6-dinitrobenzyloxy)carbonyl-N-n-hexylamine, N-(2,6-dinitrobenzyloxy)carbonyl-N-cyclohexylamine, N-(2,6-dinitrobenzyloxy)carbonyl aniline, N-(2,6-dinitrobenzyloxy)carbonylpiperidine, N,N′-bis[(2,6-dinitrobenzyloxy)carbonyl]-1,6-hexamethylenediamine, N,N′-bis[(2,6-dinitrobenzyloxy)carbonyl]-1,4-phenylenediamine, N,N′-bis[(2,6-dinitrobenzyloxy)carbonyl]-2,4-tolylenediamine, N,N′-bis[(2,6-dinitrobenzyloxy)carbonyl]-4,4-diaminodiphenylmethane, N,N′-bis[(2,6-dinitrobenzyloxy)carbonyl]piperazine, N-(α,α-dimethyl-3,5-dimethoxybenzyloxy)carbonyl-N-methylamine, N-(α,α-dimethyl-3,5-dimethoxybenzyloxy)carbonyl-N-n-propylamine, N-(α,α-dimethyl-3,5-dimethoxybenzyloxy)carbonyl-N-n-hexylamine, N-(α,α-dimethyl-3,5-dimethoxybenzyloxy)carbonyl-N-cyclohexylamine, N-(α,α-dimethyl-3,5-dimethoxybenzyloxy)carbonylaniline, N-(α,α-dimethyl-3,5-dimethoxybenzyloxy)carbonylpiperidine, N,N′-bis[(α,α-dimethyl-3,5-dimethoxybenzyloxy)carbonyl]-1,6-hexamethylenediamine, N,N′-bis[(α,α-dimethyl-3,5-dimethoxybenzyloxy)carbonyl]-1,4-phenylenediamine, N,N′-bis[(α,α-dimethyl-3,5-dimethoxybenzyloxy)carbonyl]-2,4-tolylenediamine, N,N′-bis[(α,α-dimethyl-3,5-dimethoxybenzyloxy)carbonyl]-4,4′-diaminodiphenylmethane, and N,N′-bis[(α,α-dimethyl-3,5-dimethoxybenzyloxy)carbonyl]piperazine.

In addition, it is also preferable that the carbamate compound is a compound represented by Formula (PBG-1).

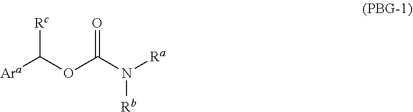

In Formula (PEG-1), R^{a} and R^{b} each independently represent a hydrogen atom or a monovalent organic group, R^{a} and R^{b} may be bonded to each other to form a cyclic amino group, R^{c} represents a hydrogen atom or a methyl group, and Ar^{a} represents an aromatic group.

Examples of the monovalent organic group represented by R^{a} and R^{b} include an aliphatic hydrocarbon group, an aromatic hydrocarbon group, and a group formed by a combination thereof.

The number of carbon atoms in the aliphatic hydrocarbon group is preferably 1 to 20, more preferably 1 to 10, and particularly preferably 1 to 5. The aliphatic hydrocarbon group may be linear, branched, or cyclic. In addition, the cyclic aliphatic hydrocarbon group may be a single ring or a polycyclic ring. Examples of the aliphatic hydrocarbon group include an alkyl group, an alkenyl group, and an alkynyl group.

The number of carbon atoms in the aromatic hydrocarbon group is preferably 6 to 18, more preferably 6 to 14, and still more preferably 6 to 10. The aromatic hydrocarbon group is preferably a single ring or a fused ring having 2 to 4 fused numbers. Examples of the aromatic hydrocarbon group include an aryl group.

The aliphatic hydrocarbon group and the aromatic hydrocarbon group may have a substituent. Examples of the substituent include groups in the description of the substituent T later.

R^{a} and R^{b} each independently represent preferably an aliphatic hydrocarbon group, more preferably an alkyl group, still more preferably a linear or branched alkyl group having 1 to 10 carbon atoms, even more preferably a linear or branched alkyl group having 1 to 5 carbon atoms, and particularly preferably a methyl group, an ethyl group, or an isopropyl group.

R^{a} and R^{b} may be bonded to each other to form a cyclic amino group. Examples of the cyclic amino group to be formed include a 1-aziridinyl group, a 1-azetidinyl group, a 1-pyrrolindinyl group, a 1-piperidinyl group, a 1-hexamethyleneimino group, a 1-heptamethyleneimino group, a 1-octamethyleneimino group, a 1-nonamethyleneimino group, a 1-1-imidazolyl group, a 4,5-dihydro-1-imidazolyl group, a 1-pyrrolyl group, a 1-pyrazolyl group, a 1-imidazolidinyl group, a 1-piperazinyl group, and a morpholino group.

The cyclic amino group formed by bonding R^{a} and R^{b} to each other may have a substituent. Examples of the substituent include groups in the description of the substituent T later.

Examples of the aromatic group represented by Ar^{a} include an aromatic hydrocarbon group and an aromatic heterocyclic group. The aromatic group represented by Ar^{a} may be a monocyclic aromatic group, but is preferably a fused aromatic group having a fused number of 2 to 4.

Examples of the aromatic hydrocarbon group include a benzene ring group, a naphthalene ring group, an anthracene ring group, and a fluorene ring group.

Examples of the aromatic heterocyclic group include a pyrrole ring group, a furan ring group, a thiophene ring group, a pyridine ring group, an imidazole ring group, a pyrazole ring group, an oxazole ring group, a thiazole ring group, a pyridazine ring group, a pyrimidine ring group, a pyrazine ring group, an indole ring group, an isoindole ring group, a benzimidazole ring group, a benzoxazole ring group, a benzothiazole ring group, a benzotriazole ring group, a quinoline ring group, an isoquinoline ring group, a quinazoline ring group, a quinoxaline ring group and an anthraquinone ring group.

The aromatic group represented by Ar^{a} may have a substituent. Examples of the substituent include groups in the description of the substituent T later.

Examples of the above-described substituent T include the following groups:

a halogen atom (for example, a fluorine atom, a chlorine atom, a bromine atom, and an iodine atom), an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), a heterocyclic group (preferably a heterocyclic group having 1 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heterocyclic oxy group (preferably a heterocyclic oxy group having 1 to 30 carbon atoms), an acyl group (preferably an acyl group having 2 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), a heterocyclic oxycarbonyl group (preferably a heterocyclic oxycarbonyl group having 2 to 30 carbon atoms), an acyloxy group (preferably an acyloxy group having 2 to 30 carbon atoms), an acylamino group (preferably an acylamino group having 2 to 30 carbon atoms), an aminocarbonylamino group (preferably an aminocarbonylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a sulfamoylamino group (preferably a sulfamoylamino group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heterocyclic thio group (preferably a heterocyclic thio group having 1 to 30 carbon atoms), an alkylsulfonyl group (preferably an alkylsulfonyl group having 1 to 30 carbon atoms), an alkylsulfonylamino group (preferably an alkylsulfonylamino group having 1 to 30 carbon atoms), an arylsulfonyl group (preferably an arylsulfonyl group having 6 to 30 carbon atoms), an arylsulfonylamino group (preferably an arylsulfonylamino group having 6 to 30 carbon atoms), a heterocyclic sulfonyl group (preferably a heterocyclic sulfonyl group having 1 to 30 carbon atoms), a heterocyclic sulfonylamino group (preferably a heterocyclic sulfonylamino group having 1 to 30 carbon atoms), an alkylsulfinyl group (preferably an alkylsulfinyl group having 1 to 30 carbon atoms), an arylsulfinyl group (preferably an arylsulfinyl group having 6 to 30 carbon atoms), a heterocyclic sulfinyl group (preferably a heterocyclic sulfinyl group having 1 to 30 carbon atoms), a ureide group (preferably a ureide group having 1 to 30 carbon atoms), a hydroxy group, a nitro group, a carboxy group, a sulfo group, a phosphoric acid group, a carboxylic acid amide group, a sulfonic acid amide group, an imide group, a phosphino group, a mercapto group, a cyano group, an alkylsulfino group, an arylsulphino group, an arylazo group, a heterocyclic azo group, a phosphinyl group, a phosphinyloxy group, a phosphinylamino group, a silyl group, a hydradino group, an imino group, a vinyl group, a styrene group, a (meth)allyl group, a (meth)acryloyl group, a (meth)acryloyloxy group. In a case where the above-described groups can be further substituted, the groups may further have a substituent.

Specific examples of the compound represented by Formula (PBG-1) include compounds having structures described in Examples later.

Examples of the acyl oxime compound include acetophenone-O-propanoyloxime, benzophenone-O-propanoyloxime, acetone-O-propanoyloxime, acetophenone-O-butanoyloxime, benzophenone-O-butanoyloxime, acetone-O-butanoyloxime, bis(acetophenone)-O,O′-hexane-1,6-dioyloxime, bis(benzophenone)-O,O′-hexane-1,6-dioyloxime, bis(acetone)-O,O′-hexane-1,6-dioyloxime, acetophenone-O-acryloyloxime, benzophenone-O-acryloyloxime, and acetone-O-acryloyloxime.

Examples of a commercially available product of the photobase generator include WPBG series (for example, WPBG-018, WPBG-027, WPBG-082, WPBG-140, WPBG-165, WPBG-167, WPBG-168, WPBG-140, and the like) manufactured by FUJIFILM Wako Pure Chemical Corporation.

A content of the generator in the total solid content of the composition is preferably 1% to 15% by mass, and from the viewpoint that a cured film having excellent moisture resistance and a low refractive index is easily formed, it is more preferably 1% to 10% by mass. The lower limit is preferably 2% by mass or more and more preferably 2.5% by mass or more. The upper limit is preferably 9% by mass or less and more preferably 8% by mass or less.

In addition, the total content of the specific particles (particles having a silanol group) and the generator in the total solid content of the composition is preferably 45% to 99% by mass. The lower limit is preferably 60% by mass or more and more preferably 80% by mass or more. The upper limit is preferably 98% by mass or less and more preferably 97% by mass or less.

In a case where the acid generator is used as the generator, a content of the acid generator (preferably, a content of the photoacid generator) in the total solid content of the composition is preferably 1% to 15% by mass, and from the viewpoint that a cured film having excellent moisture resistance and a low refractive index is easily formed, it is more preferably 1% to 10% by mass. The lower limit is preferably 2% by mass or more and more preferably 2.5% by mass or more. The upper limit is preferably 9% by mass or less and more preferably 8% by mass or less.

In addition, the total content of the specific particles and the acid generator in the total solid content of the composition is preferably 45% to 99% by mass. The lower limit is preferably 60% by mass or more and more preferably 80% by mass or more. The upper limit is preferably 98% by mass or less and more preferably 97% by mass or less.

In addition, the total content of the specific particles and the photoacid generator in the total solid content of the composition is preferably 45% to 99% by mass. The lower limit is preferably 60% by mass or more and more preferably 80% by mass or more. The upper limit is preferably 98% by mass or less and more preferably 97% by mass or less.

In a case where the base generator is used as the generator, a content of the base generator (preferably, a content of the photobase generator) in the total solid content of the composition is preferably 1% to 15% by mass, and from the viewpoint that a cured film having excellent moisture resistance and a low refractive index is easily formed, it is more preferably 1% to 10% by mass. The lower limit is preferably 2% by mass or more and more preferably 2.5% by mass or more. The upper limit is preferably 9% by mass or less and more preferably 8% by mass or less.

In addition, the total content of the specific particles and the base generator in the total solid content of the composition is preferably 45% to 99% by mass. The lower limit is preferably 60% by mass or more and more preferably 80% by mass or more. The upper limit is preferably 98% by mass or less and more preferably 97% by mass or less.

In addition, the total content of the specific particles and the photobase generator in the total solid content of the composition is preferably 45% to 99% by mass. The lower limit is preferably 60% by mass or more and more preferably 80% by mass or more. The upper limit is preferably 98% by mass or less and more preferably 97% by mass or less.

### <<Solvent>>

The composition according to the embodiment of the present invention contains a solvent. Examples of the solvent include an organic solvent and water, and it is preferable to include at least an organic solvent. Examples of the organic solvent include an aliphatic hydrocarbon-based solvent, a halogenated hydrocarbon-based solvent, an alcohol-based solvent, an ether-based solvent, an ester-based solvent, a ketone-based solvent, a nitrile-based solvent, an amide-based solvent, a sulfoxide-based solvent, and an aromatic solvent.

Examples of the aliphatic hydrocarbon-based solvent include hexane, cyclohexane, methylcyclohexane, pentane, cyclopentane, heptane, and octane.

Examples of the halogenated hydrocarbon-based solvent include methylene chloride, chloroform, dichloromethane, ethane dichloride, carbon tetrachloride, trichloroethylene, tetrachloroethylene, epichlorohydrin, monochlorobenzene, o-dichlorobenzene, allyl chloride, methyl monochloroacetate, ethyl monochloroacetate, monochloroacetic acid, trichloroacetic acid, methyl bromide, and tri(tetra)chlorethylene.

Examples of the alcohol-based solvent include methanol, ethanol, 1-propanol, 2-propanol, 2-butanol, ethylene glycol, propylene glycol, glycerin, 1,6-hexanediol, cyclohexanediol, sorbitol, xylitol, 2-methyl-2,4-pentanediol, 3-methoxy-1-butanol, 1,3-butanediol, and 1,4-butanediol.

Examples of the ether-based solvent include dimethyl ether, diethyl ether, diisopropyl ether, dibutyl ether, t-butyl methyl ether, cyclohexylmethyl ether, anisole, tetrahydrofuran, diethylene glycol, triethylene glycol, polyethylene glycol, dipropylene glycol, ethylene glycol monomethyl ether, ethylene glycol monobutyl ether, ethylene glycol monophenyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol dimethyl ether, diethylene glycol diethyl ether, diethylene glycol dipropyl ether, diethylene glycol dibutyl ether, dipropylene glycol monomethyl ether, dipropylene glycol dimethyl ether, dipropylene glycol monoethyl ether, dipropylene glycol monopropyl ether, dipropylene glycol monobutyl ether, dipropylene glycol methyl-n-propyl ether, triethylene glycol monomethyl ether, triethylene glycol monobutyl ether, tripropylene glycol monomethyl ether, tripropylene glycol monobutyl ether, tetraethylene glycol dimethyl ether, polyethylene glycol monomethyl ether, and polyethylene glycol dimethyl ether.

Examples of the ester-based solvent include propylene carbonate, dipropylene, 1,4-butanediol diacetate, 1,3-butylene glycol diacetate, 1,6-hexanediol diacetate, cyclohexanol acetate, dipropylene glycol methyl ether acetate, methyl acetate, ethyl acetate, isopropyl acetate, n-propyl acetate, butyl acetate, ethylene glycol monomethyl ether acetate, propylene glycol monomethyl ether acetate, 3-methoxybutyl acetate, ethylene glycol monobutyl ether acetate, diethylene glycol monoethyl ether acetate, diethylene glycol monobutyl ether acetate, and triacetin.

Examples of the ketone-based solvent include acetone, methyl ethyl ketone, methyl isobutyl ketone, cyclopentanone, cyclohexanone, and 2-heptanone.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, 2-pyrrolidinone, ε-caprolactam, formamide, N-methylformamide, acetamide, N-methylacetamide, N,N-dimethylacetamide, N-methylpropaneamide, hexamethylphosphoric triamide, 3-methoxy-N,N-dimethylpropaneamide, and 3-butoxy-N,N-dimethylpropaneamide.

Examples of the sulfoxide-based solvent include dimethyl sulfoxide.

Examples of the aromatic solvent include benzene and toluene.

As the solvent, from the reason that it is easy to form a film in which generation of thickness unevenness or defects is further suppressed, it is preferable to use a solvent including an alcohol-based solvent. The alcohol-based solvent is preferably at least one selected from methanol, ethanol, 1-propanol, 2-propanol, or 2-butanol, and more preferably at least one selected from methanol and ethanol. Among these, the alcohol-based solvent preferably includes at least methanol, and from the reason that it is easy to form a film in which generation of defects is further suppressed, more preferably includes methanol and ethanol.

A content of the solvent in the composition is preferably 70% to 99% by mass. The upper limit is preferably 93% by mass or less, more preferably 92% by mass or less, and still more preferably 90% by mass or less. The lower limit is preferably 75% by mass or more, more preferably 80% by mass or more, and still more preferably 85% by mass or more.

In addition, the content of the alcohol-based solvent in the total amount of the solvent is preferably 0.1% to 10% by mass. The upper limit is preferably 8% by mass or less, more preferably 6% by mass or less, and still more preferably 4% by mass or less. The lower limit is preferably 0.3% by mass or more, more preferably 0.5% by mass or more, and still more preferably 1% by mass or more. The alcohol-based solvent may be used singly or in combination of two or more kinds thereof. In a case where the composition according to the embodiment of the present invention contains two or more kinds of alcohol-based solvents, it is preferable that the total amount thereof is within the above-described range.

As the solvent, a solvent including a solvent A1 which has a boiling point of 190° C. or higher and 280° C. or lower is preferably used. In the present specification, the boiling point of a solvent is a value at 1 atm (0.1 MPa).

The boiling point of the solvent A1 is preferably 200° C. or higher, more preferably 210° C. or higher, and still more preferably 220° C. or higher. In addition, the boiling point of the solvent A1 is preferably 270° C. or lower and still more preferably 265° C. or lower.

The viscosity of the solvent A1 is preferably 10 mPa·s or less, more preferably 7 mPa·s or less, and still more preferably 4 mPa·s or less. From the viewpoint of application properties, the lower limit of the viscosity of the solvent A1 is preferably 1.0 mPa·s or more, more preferably 1.4 mPa·s or more, and still more preferably 1.8 mPa·s or more.

The molecular weight of the solvent A1 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A1 is preferably 8.5 to 13.3 (cal/cm³)^{0.5}. The upper limit is preferably 12.5 (cal/cm³)^{0.5} or less, more preferably 11.5 (cal/cm³)^{0.5} or less, and still more preferably 10.5 (cal/cm³)^{0.5} or less. The lower limit is preferably 8.7 (cal/cm³)^{0.5} or more, more preferably 8.9 (cal/cm³)^{0.5} or more, and still more preferably 9.1 (cal/cm³)^{0.5} or more. In a case where the solubility parameter of the solvent A1 is within the above-described range, high affinity with the specific particles such as silica particles is obtained, and excellent application properties are easily obtained. 1 (cal/cm³)^{0.5} is 2.0455 MPa^{0.5}. In addition, the solubility parameter of a solvent is a value calculated by HSPiP.

In the present specification, the Hansen solubility parameter is used as the solubility parameter of the solvent. Specifically, a value calculated by using the Hansen solubility parameter software “HSPiP 5.0.09” is used.

The solvent A1 is preferably an aprotic solvent. In a case where an aprotic solvent is used as the solvent A1, aggregation of the specific particles such as silica particles during film formation can be more effectively suppressed, and it is easy to form a film in which generation of thickness unevenness or defects is further suppressed.

The solvent A1 is preferably an ether-based solvent or an ester-based solvent, and more preferably an ester-based solvent. In addition, the ester-based solvent used as the solvent A1 is preferably a compound not including a hydroxy group or a terminal alkoxy group. By using an ester-based solvent not having such a functional group, it is easy to form a film in which generation of thickness unevenness or defects is further suppressed.

From the viewpoint that high affinity with the specific particles such as silica particles is obtained, and excellent application properties are easily obtained, it is preferable that the solvent A1 is at least one selected from alkylene diol diacetate or cyclic carbonate. Examples of the alkylenediol diacetate include propylene glycol diacetate, 1,4-butanediol diacetate, 1,3-butylene glycol diacetate, and 1,6-hexanediol diacetate. Examples of the cyclic carbonate include propylene carbonate and ethylene carbonate.

Specific examples of the solvent A1 include propylene carbonate (boiling point: 240° C.), ethylene carbonate (boiling point: 260° C.), propylene glycol diacetate (boiling point: 190° C.), dipropylene glycol methyl-n-propyl ether (boiling point: 203° C.), dipropylene glycol methyl ether acetate (boiling point: 213° C.), 1,4-butanediol diacetate (boiling point: 232° C.), 1,3-butylene glycol diacetate (boiling point: 232° C.), 1,6-hexanediol diacetate (boiling point: 260° C.), diethylene glycol monoethyl ether acetate (boiling point: 217° C.), diethylene glycol monobutyl ether acetate (boiling point: 247° C.), triacetin (boiling point: 260° C.), dipropylene glycol monomethyl ether (boiling point: 190° C.), diethylene glycol monoethyl ether (boiling point: 202° C.), dipropylene glycol monopropyl ether (boiling point: 212° C.), dipropylene glycol monobutyl ether (boiling point: 229° C.), tripropylene glycol monomethyl ether (boiling point: 242° C.), and tripropylene glycol monobutyl ether (boiling point: 274° C.).

A content of the above-described solvent A1 in the solvent contained in the composition is preferably 3% by mass or more, more preferably 4% by mass or more, and still more preferably 5% by mass or more. The upper limit is preferably 20% by mass or less, more preferably 15% by mass or less, and still more preferably 12% by mass or less. The solvent A1 may be used singly or in a combination of two or more kinds thereof. In a case where two or more types of solvents A1 are contained, it is preferable that the total amount thereof is within the above-described range.

It is also preferable that the solvent contained in the composition further includes a solvent A2 having a boiling point of 110° C. or higher and lower than 190° C., in addition to the above-described solvent A1. According to this aspect, it is easy to form a film in which drying properties of the composition are appropriately increased and the thickness unevenness is further suppressed.

The boiling point of the solvent A2 is preferably 115° C. or higher, more preferably 120° C. or higher, and still more preferably 130° C. or higher. In addition, the boiling point of the solvent A2 is preferably 170° C. or lower and still more preferably 150° C. or lower. In a case where the boiling point of the solvent A2 is within the above-described range, the above-described effects are easily obtained more remarkably.

From the reason that the above-described effects are easily obtained more remarkably, the molecular weight of the solvent A2 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A2 is preferably 9.0 to 11.4 (cal/cm³)^{0.5}. The upper limit is preferably 11.0 (cal/cm³)^{0.5} or less, more preferably 10.6 (cal/cm³)^{0.5} or less, and still more preferably 10.2 (cal/cm³)^{0.5} or less. The lower limit is preferably 9.2 (cal/cm³)^{0.5} or more, more preferably 9.4 (cal/cm³)^{0.5} or more, and still more preferably 9.6 (cal/cm³)^{0.5} or more. In a case where the solubility parameter of the solvent A2 is within the above-described range, high affinity with the specific particles such as silica particles is obtained, and excellent application properties are easily obtained. In addition, the absolute value of a difference between the solubility parameter of the solvent A1 and the solubility parameter of the solvent A2 is preferably 0.01 to 1.1 (cal/cm³)^{0.5}. The upper limit is preferably 0.9 (cal/cm³)^{0.5} or less, more preferably 0.7 (cal/cm³)^{0.5} or less, and still more preferably 0.5 (cal/cm³)^{0.5} or less. The lower limit is preferably 0.03 (cal/cm³)^{0.5} or more, more preferably 0.05 (cal/cm³)^{0.5} or more, and still more preferably 0.08 (cal/cm³)^{0.5} or more.

The solvent A2 is preferably at least one selected from an ether-based solvent or an ester-based solvent, more preferably includes at least an ester-based solvent, and still more preferably includes an ether-based solvent and an ester-based solvent. Specific examples of the solvent A2 include cyclohexanol acetate (boiling point: 173° C.), dipropylene glycol dimethyl ether (boiling point: 175° C.), butyl acetate (boiling point: 126° C.), ethylene glycol monomethyl ether acetate (boiling point: 145° C.), propylene glycol monomethyl ether acetate (boiling point: 146° C.), 3-methoxybutyl acetate (boiling point: 171° C.), propylene glycol monomethyl ether (boiling point: 120° C.), 3-methoxybutanol (boiling point: 161° C.), propylene glycol monopropyl ether (boiling point: 150° C.), propylene glycol monobutyl ether (boiling point: 170° C.), and ethylene glycol monobutyl ether acetate (boiling point: 188° C.), and from the reason that high affinity with the specific particles such as silica particles can be obtained and excellent application properties can be easily obtained, it is preferable to include at least propylene glycol monomethyl ether acetate.

In a case where the solvent used in the composition includes the solvent A2, a content of the solvent A2 is preferably 500 to 5000 parts by mass with respect to 100 parts by mass of the solvent A1. The upper limit is preferably 4500 parts by mass or less, more preferably 4000 parts by mass or less, and still more preferably 3500 parts by mass or less. The lower limit is preferably 600 parts by mass or more, more preferably 700 parts by mass or more, and still more preferably 750 parts by mass or more. In addition, the content of the solvent A2 in the total amount of the solvent is preferably 50% by mass or more, more preferably 60% by mass or more, and still more preferably 70% by mass or more. The upper limit is preferably 95% by mass or less, more preferably 90% by mass or less, and still more preferably 85% by mass or less. The solvent A2 may be used singly or in a combination of two or more kinds thereof. In a case where two or more types of solvents A2 are contained, it is preferable that the total amount thereof is within the above-described range.

In addition, the total content of the solvent A1 and the solvent A2 in the solvent used in the composition is preferably 62% by mass or more, more preferably 72% by mass or more, and still more preferably 82% by mass or more. The upper limit may be 100% by mass, 96% by mass or less, or 92% by mass or less.

It is also preferable that the solvent used in the composition further includes water. According to this aspect, high affinity with the specific particles such as silica particles is obtained, and excellent application properties are easily obtained. In a case where the solvent used in the composition further includes water, a content of the water in the total amount of the solvent is preferably 0.1% to 5% by mass. The upper limit is preferably 4% by mass or less, more preferably 2.5% by mass or less, and still more preferably 1.5% by mass or less. The lower limit is preferably 0.3% by mass or more, more preferably 0.5% by mass or more, and still more preferably 0.7% by mass or more. In a case where the content of water is within the above-described range, the above-described effects are easily obtained more remarkably.

The solvent used in the composition can further include a solvent A3 having a boiling point of higher than 280° C. According to this aspect, it is easy to form a film in which drying properties of the composition are appropriately increased and generation of thickness unevenness or defects is further suppressed. The upper limit of the boiling point of the solvent A3 is preferably 400° C. or lower, more preferably 380° C. or lower, and still more preferably 350° C. or lower. The solvent A3 is preferably at least one selected from an ether-based solvent or an ester-based solvent. Specific examples of the solvent A3 include polyethylene glycol monomethyl ether. In a case where the solvent used in the composition further includes the solvent A3, a content of the solvent A3 in the total amount of the solvent is preferably 0.5% to 15% by mass. The upper limit is preferably 10% by mass or less, more preferably 8% by mass or less, and still more preferably 6% by mass or less. The lower limit is preferably 1% by mass or more, more preferably 1.5% by mass or more, and still more preferably 2% by mass or more. In addition, it is also preferable that the solvent used in the composition does not substantially contain the solvent A3. The case where the solvent does not substantially contain the solvent A3 means that the content of the solvent A3 in the total amount of the solvent is 0.1% by mass or less, preferably 0.05% by mass or less, more preferably 0.01% by mass or less, and still more preferably 0% by mass.

In the solvent used in the composition, a content of a compound having a molecular weight (weight-average molecular weight in a case of a polymer) of more than 300 is preferably 10% by mass or less, more preferably 8% by mass or less, still more preferably 5% by mass or less, even more preferably 3% by mass or less, and particularly preferably 1% by mass or less. According to this aspect, it is easy to form a film in which generation of thickness unevenness or defects is further suppressed.

In the solvent used in the composition, a content of a compound having a viscosity of more than 10 mPa·s at 25° C. is preferably 10% by mass or less, more preferably 8% by mass or less, still more preferably 5% by mass or less, even more preferably 3% by mass or less, and particularly preferably 1% by mass or less. According to this aspect, it is easy to form a film in which generation of thickness unevenness or defects is further suppressed.

### <<Silanol Compound Having Molecular Weight of 1,000 or Less>>

The composition according to the embodiment of the present invention may contain a silanol compound having a molecular weight of 1,000 or less. Hereinafter, the silanol compound having a molecular weight of 1,000 or less is also referred to as a low-molecular-weight silanol compound. The low-molecular-weight silanol compound is a material different from the above-described particles having a silanol group.

The low-molecular-weight silanol compound is preferably a compound which is easily soluble in water. In addition, an amount of the low-molecular-weight silanol compound dissolved in 100 g of water at 25° C. or in 100 g of propylene glycol monomethyl ether acetate at 25° C. is preferably 5 g or more and more preferably 10 g or more.

The molecular weight of the low-molecular-weight silanol compound is preferably 950 or less, more preferably 900 or less, and still more preferably 800 or less.

A silanol group value of the low-molecular-weight silanol compound is preferably 0.1 to 10 mmol/g. The upper limit of the silanol group value is preferably 7 mmol/g or less and more preferably 5 mmol/g or less. The lower limit of the silanol group value is preferably 0.5 mmol/g or more and more preferably 1 mmol/g or more. The silanol group value of the low-molecular-weight silanol compound is a numerical value representing the molar amount of a silanol group per 1 g of solid contents of the low-molecular-weight silanol compound. The silanol group value of the low-molecular-weight silanol compound can be calculated by dividing the number of silanol groups included in one molecule of the low-molecular-weight silanol compound by the molecular weight of the low-molecular-weight silanol compound.

The low-molecular-weight silanol compound may further have a functional group such as a carboxy group, an amino group, a mercapto group, a (meth)acryloyl group, an isocyanate group, and an epoxy group. By further having these functional groups, a crosslinking density of the film can be further increased. The above-described functional group is preferably a carboxy group, an amino group, a (meth)acryloyl group, or a mercapto group, and more preferably a carboxy group or an amino group.

Examples of the low-molecular-weight silanol compound include X-12-1135 and KBP-90 (both of which are manufactured by Shin-Etsu Chemical Co., Ltd.), and KBP-64, X-12-1098, X-12-1135, X-12-1139, and X-12-1126 (all of which are manufactured by Shin-Etsu Chemical Co., Ltd.).

A content of the low-molecular-weight silanol compound in the composition according to the embodiment of the present invention is preferably 0.1% to 10% by mass. The lower limit is preferably 0.2% by mass or more and more preferably 0.5% by mass or more. The upper limit is preferably 7.5% by mass or less and more preferably 5% by mass or less.

In addition, the content of the low-molecular-weight silanol compound in the total solid content of the composition according to the embodiment of the present invention is preferably 1% to 20% by mass. The lower limit is preferably 3% by mass or more and more preferably 5% by mass or more. The upper limit is preferably 15% by mass or less and more preferably 10% by mass or less. The composition according to the embodiment of the present invention may contain only one kind of low-molecular-weight silanol compound, or may contain two or more kinds thereof. In a case where the composition according to the embodiment of the present invention contains two or more kinds of low-molecular-weight silanol compounds, it is preferable that the total amount thereof is within the above-described range.

### <<Surfactant>>

The composition according to the embodiment of the present invention may contain a surfactant. As the surfactant, various surfactants such as a fluorine-based surfactant, a nonionic surfactant, a cationic surfactant, an anionic surfactant, and a silicone-based surfactant can be used. The surfactant is preferably a fluorine-based surfactant or a silicone-based surfactant, and more preferably a silicone-based surfactant. In the present specification, the silicone-based surfactant is a compound having a repeating unit including a siloxane bond in the main chain, and is a compound including a hydrophobic part and a hydrophilic part in one molecule.

Examples of the fluorine-based surfactant include surfactants described in paragraphs 0060 to 0064 of JP2014-041318A (paragraphs 0060 to 0064 of the corresponding WO2014/017669A) and the like, surfactants described in paragraphs 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, R-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (all of which are manufactured by NEOS COMPANY LIMITED).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

It is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraphs 0016 to 0037 of JP2010-032698A, or the following compounds are also exemplified as the fluorine-based surfactant used in the present invention.

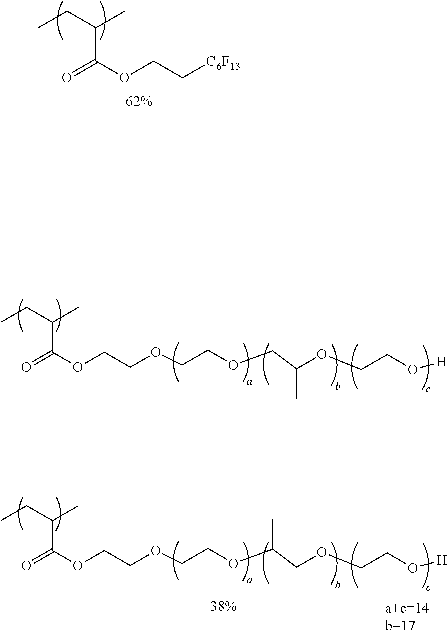

A weight-average molecular weight of the compound is preferably 3,000 to 50,000 and, for example, 14,000. In the compound, “%” representing the proportion of a repeating unit is mol %.

In addition, as the fluorine-based surfactant, a fluorine-containing polymer having an ethylenically unsaturated bond-containing group at a side chain can also be used. Specific examples thereof include compounds described in paragraphs 0050 to 0090 and paragraphs 0289 to 0295 of JP2010-164965A, and MEGAFACE RS-101, RS-102, RS-718K, and RS-72-K manufactured by DIC Corporation. In addition, as the fluorine-based surfactant, a compound described in paragraphs 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

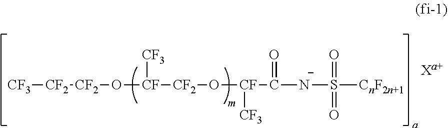

In Formula (fi-1), m represents 1 or 2, n represents an integer of 1 to 4, a represents 1 or 2, and X^{a+} represents an a-valent metal ion, a primary ammonium ion, a secondary ammonium ion, a tertiary ammonium ion, a quaternary ammonium ion, or NH₄⁺.

The silicone-based surfactant is preferably a compound which does not include a fluorine atom. The silicone-based surfactant is preferably a modified silicone compound. Examples of the modified silicone compound include compounds having a structure in which an organic group is introduced into a side chain and/or a terminal of polysiloxane. Examples of the organic group include a group having a functional group selected from an amino group, an epoxy group, an alicyclic epoxy group, a carbinol group, a mercapto group, a carboxyl group, a fatty acid ester group, and a fatty acid amide group, and a group having a polyether chain; and a group having a carbinol group or a group having a polyether chain is preferable.

Specific examples of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by Dow TORAY); TSF-4440, TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-3760, and BYK-UV3510 (all of which are manufactured by BYK Chemie).

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

A content of the surfactant in the composition according to the embodiment of the present invention is preferably 0.01% to 0.3% by mass. From the viewpoint of easily suppressing the occurrence of wave-like coating unevenness more effectively, the lower limit is preferably 0.05% by mass or more, more preferably 0.1% by mass or more, and still more preferably 0.15% by mass or more. The upper limit is preferably 0.28% by mass or less, more preferably 0.25% by mass or less, and still more preferably 0.2% by mass or less. In addition, the content of the surfactant in the total solid content of the composition according to the embodiment of the present invention is preferably 0.05% to 5.00% by mass. From the viewpoint of easily suppressing the occurrence of wave-like coating unevenness more effectively, the lower limit is preferably 0.1% by mass or more, more preferably 0.5% by mass or more, and still more preferably 1.2% by mass or more. The upper limit is preferably 4% by mass or less and more preferably 3% by mass or less. The composition according to the embodiment of the present invention may contain only one kind of surfactant, or may contain two or more kinds thereof. In a case where the composition according to the embodiment of the present invention contains two or more kinds of surfactants, it is preferable that the total amount thereof is within the above-described range.

### <<Dispersant>>

The composition according to the embodiment of the present invention can contain a dispersant. Examples of the dispersant include polymer dispersants (for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate), polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant adsorbs on a surface of particles and acts to prevent reaggregation. Therefore, examples of a preferred structure of the polymer dispersant include a terminal-modified polymer, a graft polymer, and a block polymer, each of which has an anchor site for adsorbing on the particle surface. A commercially available product can also be used as the dispersant. Examples thereof include products described in paragraph 0050 of WO2016/190374A, the contents of which are incorporated herein by reference.

A content of the dispersant is preferably 1 to 100 parts by mass, more preferably 3 to 100 parts by mass, and still more preferably 5 to 80 parts by mass with respect to 100 parts by mass of the specific particles. In addition, the content of the dispersant in the total solid content of the composition is preferably 1 to 30% by mass. As the dispersant, one kind may be included, or two or more kinds may be included. In a case where two or more kinds of dispersants are contained, it is preferable that the total amount thereof is within the above-described range.

### <<Radically Polymerizable Monomer>>

The composition according to the embodiment of the present invention may contain a radically polymerizable monomer. The radically polymerizable monomer is preferably a compound having an ethylenically unsaturated bond-containing group. In addition, the radically polymerizable monomer is preferably a compound not including a silanol group.

A molecular weight of the radically polymerizable monomer is preferably 100 to 3,000. The upper limit is more preferably 2,000 or less and still more preferably 1,500 or less. The lower limit is more preferably 150 or more and still more preferably 250 or more.

The radically polymerizable monomer is preferably a compound having two or more ethylenically unsaturated bond-containing groups, and more preferably a compound having three or more ethylenically unsaturated bond-containing groups. The upper limit of the number of the ethylenically unsaturated bond-containing groups is, for example, preferably 15 or less and more preferably 6 or less. Examples of the ethylenically unsaturated bond-containing group include a vinyl group, a styrene group, a (meth)allyl group, and a (meth)acryloyl group, and a (meth)acryloyl group is preferable. The radically polymerizable monomer is preferably a (meth)acrylate compound having 3 to 15 functional groups and more preferably a (meth)acrylate compound having 3 to 6 functional groups. Specific examples of the radically polymerizable monomer include compounds described in paragraphs 0059 to 0079 of WO2016/190374A.

As the radically polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd. and NK ESTER A-DPH-12E manufactured by Shin-Nakamura Chemical Co., Ltd.), a compound having a structure in which a (meth)acryloyl group of these compounds is bonded through an ethylene glycol residue and/or a propylene glycol residue (for example, SR454 and SR499 available from Sartomer Japan Inc.), diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), or the like can be used.

In addition, as the radically polymerizable monomer, it is also possible to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the radically polymerizable monomer, a compound having an acid group can also be used. Examples of the acid group include a carboxy group, a sulfo group, and a phosphoric acid group, and a carboxy group is preferable. Examples of a commercially available product of the radically polymerizable monomer having an acid group include ARONIX M-510, M-520, and ARONIX TO-2349 (manufactured by TOAGOSEI CO., LTD). An acid value of the radically polymerizable monomer having an acid group is preferably 0.1 to 40 mgKOH/g and more preferably 5 to 30 mgKOH/g. In a case where the acid value of the radically polymerizable monomer is 0.1 mgKOH/g or more, solubility in a developer is good, and in a case where the acid value of the radically polymerizable monomer is 40 mgKOH/g or less, it is advantageous in production and handling.

As the radically polymerizable monomer, a compound having a caprolactone structure can also be used. Examples of the radically polymerizable monomer having a caprolactone structure include DPCA-20, DPCA-30, DPCA-60, and DPCA-120, each of which is commercially available as KAYARAD DPCA series from Nippon Kayaku Co., Ltd.

As the radically polymerizable monomer, a radically polymerizable monomer having an alkyleneoxy group can also be used. The radically polymerizable monomer having an alkyleneoxy group is preferably a radically polymerizable monomer having an ethyleneoxy group and/or a propyleneoxy group, more preferably a radically polymerizable monomer having an ethyleneoxy group, and still more preferably a trifunctional to hexafunctional (meth)acrylate compound having 4 to 20 ethyleneoxy groups. Examples of a commercially available product of the radically polymerizable monomer having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the radically polymerizable monomer, a radically polymerizable monomer having a fluorene skeleton can also be used. Examples of a commercially available product of the radically polymerizable monomer having a fluorene skeleton include OGSOL EA-0200 and EA-0300 (manufactured by Osaka Gas Chemicals Co., Ltd., a (meth)acrylate monomer having a fluorene skeleton).

As the radically polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

In a case where the composition according to the embodiment of the present invention contains the radically polymerizable monomer, a content of the radically polymerizable monomer in the composition is preferably 0.1% by mass or more, more preferably 0.2% by mass or more, and still more preferably 0.5% by mass or more. The upper limit is preferably 10% by mass or less, more preferably 5% by mass or less, and still more preferably 3% by mass or less. In addition, the content of the radically polymerizable monomer in the total solid content of the composition is preferably 1% by mass or more, more preferably 2% by mass or more, and still more preferably 5% by mass or more. The upper limit is preferably 30% by mass or less, more preferably 25% by mass or less, and still more preferably 20% by mass or less. The composition according to the embodiment of the present invention may contain only one kind of radically polymerizable monomer, or may contain two or more kinds thereof. In the case where two or more kinds of radically polymerizable monomers are contained, it is preferable that the total amount thereof is within the above-described range.

In addition, it is also preferable that the composition according to the embodiment of the present invention does not substantially contain the radically polymerizable monomer. In a case where the composition according to the embodiment of the present invention does not substantially contain the radically polymerizable monomer, a film having a lower refractive index is easily formed. Furthermore, it is easy to form a film having a small haze. The case where the composition according to the embodiment of the present invention does not substantially contain the radically polymerizable monomer means that the content of the radically polymerizable monomer in the total solid content of the composition according to the embodiment of the present invention is 0.05% by mass or less, preferably 0.01% by mass or less, and more preferably 0% by mass.

### <Photoradical Polymerization Initiator>

The composition according to the embodiment of the present invention may contain a photoradical polymerization initiator. In a case where the composition according to the embodiment of the present invention contains the radically polymerizable monomer and the photoradical polymerization initiator, the composition according to the embodiment of the present invention can be preferably used as a composition for forming a pattern by a photolithography method.

Examples of the photoradical polymerization initiator include a halogenated hydrocarbon derivative (for example, a compound having a triazine skeleton or a compound having an oxadiazole skeleton), an acylphosphine compound, a hexaarylbiimidazole compound, an oxime compound, an organic peroxide, a thio compound, a ketone compound, an aromatic onium salt, an α-hydroxyketone compound, and an α-aminoketone compound. From the viewpoint of exposure sensitivity, as the photoradical polymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a hexaarylbiimidazole compound, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. In addition, as the photoradical polymerization initiator, compounds described in paragraphs 0065 to 0111 of JP2014-130173A, compounds described in JP6301489B, peroxide-based photoradical polymerization initiators described in MATERIAL STAGE, p. 37 to 60, vol. 19, No. 3, 2019, photoradical polymerization initiators described in WO2018/221177A, photoradical polymerization initiators described in WO2018/110179A, photoradical polymerization initiators described in JP2019-043864A, photoradical polymerization initiators described in JP2019-044030A, peroxide initiators described in JP2019-167313A, aminoacetophenone-based initiators described in JP2020-055992A, oxime-based photoradical polymerization initiators described in JP2013-190459A, polymers described in JP2020-172619A, and the compound represented by Formula 1 described in WO2020/152120A, the contents of which are incorporated herein by reference.

Specific examples of the hexaarylbiimidazole compound include 2,2′,4-tris(2-chlorophenyl)-5-(3,4-dimethoxyphenyl)-4,5-diphenyl-1,1′-biimidazole.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraphs 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, 2-ethoxycarbonyloxyimino-1-phenylpropane-1-one, and 1-[4-(phenylthio)phenyl]-3-cyclohexyl-propane-1,2-dione-2-(O-acetyloxime). Examples of a commercially available product thereof include Irgacure OXE01, Irgacure OXE02, Irgacure OXE03, and Irgacure OXE04 (all of which are manufactured by BASF SE), TR-PBG-304 and TR-PBG-327 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

As the photoradical polymerization initiator, an oxime compound having a fluorene ring can also be used. Specific examples of the oxime compound having a fluorene ring include compounds described in JP2014-137466A, compounds described in JP6636081B, and compounds described in KR10-2016-0109444A.

As the photoradical polymerization initiator, an oxime compound having a skeleton in which at least one benzene ring of a carbazole ring is a naphthalene ring can also be used. Specific examples of such an oxime compound include the compounds described in WO2013/083505A.

As the photoradical polymerization initiator, an oxime compound having a fluorine atom can also be used. Specific examples of the oxime compound having a fluorine atom include compounds described in JP2010-262028A, Compounds 24 and 36 to 40 described in JP2014-500852A, and Compound (C-3) described in JP2013-164471A.

As the photoradical polymerization initiator, an oxime compound having a nitro group can be used. The oxime compound having a nitro group is also preferably used in the form of a dimer. Specific examples of the oxime compound having a nitro group include a compound described in paragraphs 0031 to 0047 of JP2013-114249A and paragraphs 0008 to 0012 and 0070 to 0079 of JP2014-137466A, a compound described in paragraphs 0007 to 0025 of JP4223071B, and ADEKA ARKLS NCI-831 (manufactured by ADEKA Corporation).

As the photoradical polymerization initiator, an oxime compound having a benzofuran skeleton can also be used. Specific examples thereof include OE-01 to OE-75 described in WO2015/036910A.

As the photoradical polymerization initiator, an oxime compound in which a substituent having a hydroxy group is bonded to a carbazole skeleton can also be used. Examples of such a photoradical polymerization initiator include compounds described in WO2019/088055A.

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photoradical polymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the composition can be improved. Specific examples of the bifunctional or tri- or higher functional photoradical polymerization initiator include dimers of the oxime compounds described in JP2010-527339A, JP2011-524436A, WO2015/004565A, paragraphs 0407 to 0412 of JP2016-532675A, and paragraphs 0039 to 0055 of WO2017/033680A; the compound (E) and compound (G) described in JP2013-522445A; Cmpd 1 to 7 described in WO2016/034963A; the oxime ester-based photoinitiators described in paragraph 0007 of JP2017-523465A; the photoinitiators described in paragraphs 0020 to 0033 of JP2017-167399A; the photopolymerization initiator (A) described in paragraphs 0017 to 0026 of JP2017-151342A; and the oxime ester-based photoinitiators described in JP6469669B.

In a case where the composition according to the embodiment of the present invention contains the photoradical polymerization initiator, a content of the photoradical polymerization initiator in the composition is preferably 0.1% by mass or more, more preferably 0.2% by mass or more, and still more preferably 0.5% by mass or more. The upper limit is preferably 10% by mass or less, more preferably 5% by mass or less, and still more preferably 3% by mass or less. In addition, the content of the photoradical polymerization initiator in the total solid content of the composition is preferably 1% by mass or more, more preferably 2% by mass or more, and still more preferably 5% by mass or more. The upper limit is preferably 30% by mass or less, more preferably 25% by mass or less, and still more preferably 20% by mass or less. In addition, the content of the photoradical polymerization initiator is preferably 10 to 1000 parts by mass with respect to 100 parts by mass of the radically polymerizable monomer. The upper limit is preferably 500 parts by mass or less, more preferably 300 parts by mass or less, and still more preferably 100 parts by mass or less. The lower limit is preferably 20 parts by mass or more, more preferably 40 parts by mass or more, and still more preferably 60 parts by mass or more. The composition according to the embodiment of the present invention may contain only one kind of photoradical polymerization initiator, or may contain two or more kinds thereof. In the case where two or more kinds of photoradical polymerization initiators are contained, it is preferable that the total amount thereof is within the above-described range.

In addition, it is also preferable that the composition according to the embodiment of the present invention does not substantially contain the photoradical polymerization initiator. The case where the composition according to the embodiment of the present invention does not substantially contain the photoradical polymerization initiator means that the content of the photoradical polymerization initiator in the total solid content of the composition is 0.005% by mass or less, preferably 0.001% by mass or less, and more preferably 0% by mass.

### <<Resin>>

The composition according to the embodiment of the present invention may contain a resin. A weight-average molecular weight (Mw) of the resin is preferably 3,000 to 2,000,000. The upper limit is preferably 1,000,000 or less and more preferably 500,000 or less. The lower limit is preferably 4,000 or more. In addition, a number-average molecular weight (Mn) of the resin is preferably 3,000 to 2,000,000. The upper limit is preferably 1,000,000 or less and more preferably 500,000 or less. The lower limit is preferably 4,000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide resin, a polyamideimide resin, a polyolefin resin, a cyclic olefin resin, a polyester resin, a styrene resin, a vinyl acetate resin, a polyvinyl alcohol resin, a polyvinyl acetal resin, a polyurethane resin, a polyurea resin, and a siloxane resin. These resins may be used singly or as a mixture of two or more kinds thereof. From the viewpoint of improving heat resistance, as the cyclic olefin resin, a norbornene resin is preferable. Examples of a commercially available product of the norbornene resin include ARTON series (for example, ARTON F4520) manufactured by JSR Corporation. Examples of the siloxane resin include SILAPLANE series (for example, FM-DA21, FM-3321, and the like) manufactured by JNC Corporation.

As the resin, resins described in Examples of WO2016/088645A, resins described in JP2017-057265A, resins described in JP2017-032685A, resins described in JP2017-075248A, resins described in JP2017-066240A, resins described in JP2017-167513A, resins described in JP2017-173787A, resins described in paragraphs 0041 to 0060 of JP2017-206689A, resins paragraphs 0022 to 0071 of JP2018-010856A, block polyisocyanate resins described in JP2016-222891A, resins described in JP2020-122052A, resins described in 2020-111656A, resins described in JP2020-139021A, and resins including a constitutional unit having a ring structure in the main chain and a constitutional unit having a biphenyl group in the side chain, which are described in JP2017-138503A, can also be used. In addition, as the resin, a resin having a fluorene skeleton can also be preferably used. With regard to the resin having a fluorene skeleton, reference can be made to the description in US2017/0102610A, the content of which is incorporated herein by reference. In addition, as the resin, resins described in paragraphs 0199 to 0233 of JP2020-186373A, alkali-soluble resins described in JP2020-186325A, and resins represented by Formula 1, described in KR10-2020-0078339A, can also be used.

It is also preferable to use a resin having an acid group as the resin. According to this aspect, developability can be further improved in a case of forming a pattern by a photolithography method. Examples of the acid group include a carboxy group, a phosphoric acid group, a sulfo group, and a phenolic hydroxyl group, and a carboxy group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. A weight-average molecular weight (Mw) of the resin having an acid group is preferably 5000 to 100000. In addition, a number-average molecular weight (Mn) of the resin having an acid group is preferably 1,000 to 20,000.

A content of the resin in the total solid content of the composition is preferably 30% by mass or less, from the viewpoint that the effects of the present invention are more remarkably obtained, it is more preferably 20% by mass or less, still more preferably 10% by mass or less, even more preferably 5% by mass or less, and particularly preferably 3% by mass or less. The composition according to the embodiment of the present invention may contain only one kind of resin, or may contain two or more kinds thereof. In a case where two or more kinds of resins are contained, it is preferable that the total amount thereof is within the above-described range.

It is also preferable that the composition according to the embodiment of the present invention does not substantially contain the resin. In the present specification, the case where the composition does not substantially contain the resin means that the content of the resin in the total solid content of the composition is 0.1% by mass or less, preferably 0.05% by mass or less and more preferably 0% by mass.

### <<Adhesion Improver>>

The composition according to the embodiment of the present invention may contain an adhesion improver. By containing the adhesion improver, a cured film having excellent adhesiveness to the support can be formed. Suitable examples of the adhesion improver include adhesion improvers described in JP1993-011439A (JP-H05-011439A), JP1993-341532A (JP-H05-341532A), JP1994-043638A (JP-H06-043638A), and the like. Specific examples thereof include benzimidazole, benzoxazole, benzthiazole, 2-mercaptobenzimidazole, 2-mercaptobenzoxazole, 2-mercaptobenzthiazole, 3-morpholinomethyl-1-phenyl-triazole-2-thione, 3-morpholinomethyl-5-phenyl-oxadiazole-2-thione, 5-amino-3-morpholinomethyl-thiadiazole-2-thione, 2-mercapto-5-methylthio-thiazole, triazole, tetrazole, benzotriazole, carboxybenzotriazole, amino group-containing benzotriazole, and a silane coupling agent. As the adhesion improver, a silane coupling agent is preferable. In the present specification, the silane coupling agent is a compound having a hydrolyzable group. The silane coupling agent is preferably a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable.

The silane coupling agent is preferably a compound having an alkoxysilyl group. Examples of the alkoxysilyl group include a monoalkoxysilyl group, a dialkoxysilyl group, and a trialkoxysilyl group, and a trialkoxysilyl group is preferable. In addition, the number of carbon atoms in an alkyl portion in the alkoxysilyl group is preferably 1 to 10, more preferably 1 to 5, still more preferably 1 to 3, even preferably 1 or 2, and particularly preferably 1. Examples of the functional group other than a hydrolyzable group include a vinyl group, a (meth)allyl group, a (meth)acryloyl group, a mercapto group, an epoxy group, an oxetanyl group, an amino group, an ureide group, a sulfide group, an isocyanate group, and a phenyl group. Among these, an amino group, a (meth)acryloyl group, or an epoxy group is preferable. In a case where the composition according to the embodiment of the present invention contains the compound having an alkoxysilyl group, curing properties can be further improved. The reason why such an effect is obtained is presumed to be that the compound having an alkoxysilyl group is hydrolyzed and condensed by the base or acid generated from the generator. In particular, in a case where the photoacid generator or the photobase generator is used as the generator, a composition having excellent photocuring properties can be obtained. Such a composition can be preferably used as a composition for forming a pattern by a photolithography method.

Specific examples of the silane coupling agent include N-β-aminoethyl-γ-aminopropyl methyldimethoxysilane (manufactured by Shin-Etsu Chemical Co., Ltd., trade name: KBM-602), N-β-aminoethyl-γ-aminopropyl trimethoxysilane (manufactured by Shin-Etsu Chemical Co., Ltd., trade name: KBM-603), N-β-aminoethyl-γ-aminopropyl triethoxysilane (manufactured by Shin-Etsu Chemical Co., Ltd., trade name: KBE-602), γ-aminopropyl trimethoxysilane (manufactured by Shin-Etsu Chemical Co., Ltd., trade name: KBM-903), γ-aminopropyl triethoxysilane (manufactured by Shin-Etsu Chemical Co., Ltd., trade name: KBE-903), 3-methacryloxypropyl methyldimethoxysilane (manufactured by Shin-Etsu Chemical Co., Ltd., trade name: KBM-502), 3-methacryloxypropyl trimethoxysilane (manufactured by Shin-Etsu Chemical Co., Ltd., trade name: KBM-503), 8-glycidoxyoctyl trimethoxysilane (manufactured by Shin-Etsu Chemical Co., Ltd., trade name: KBM-4803), 1,8-bis(trimethoxysilyl)octane (manufactured by Shin-Etsu Chemical Co., Ltd., trade name: KBM-3086), tris(trimethoxysilylpropyl)isocyanurate (manufactured by Shin-Etsu Chemical Co., Ltd., trade name: KBM-9659), and X-12-5263HP (manufactured by Shin-Etsu Chemical Co., Ltd.). In addition, specific examples of the silane coupling agent include compounds described in paragraphs 0018 to 0036 of JP2009-288703A and compounds described in paragraphs 0056 to 0066 of JP2009-242604A, the contents of which are incorporated herein by reference.

In a case where the composition according to the embodiment of the present invention contains an adhesion improver, a content of the adhesion improver in the total solid content of the composition is preferably 0.001% by mass or more, more preferably 0.01% by mass or more, and particularly preferably 0.1% by mass or more. The upper limit is preferably 20% by mass or less, more preferably 10% by mass or less, and particularly preferably 5% by mass or less. The composition according to the embodiment of the present invention may contain only one kind of adhesion improver, or may contain two or more kinds thereof. In a case where two or more kinds of adhesion improvers are contained, it is preferable that the total amount thereof is within the above-described range.

### <<Other Components>>

Optionally, the composition according to the embodiment of the present invention may further contain a sensitizer, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph 0183 of JP2012-003225A (corresponding to paragraph 0237 of US2013/0034812A) and paragraphs 0101 to 0104 and 0107 to 0109 of JP2008-250074A, the contents of which are incorporated herein by reference. In addition, optionally, the composition may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

The composition according to the embodiment of the present invention may contain a colorant. Examples of the colorant include a green colorant, a red colorant, a yellow colorant, a violet colorant, a blue colorant, an orange colorant, and a black colorant.

The colorant may be a pigment or a dye. An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less.

A content of the colorant in the total solid content of the composition is preferably 10% by mass or less, more preferably 5% by mass or less, and particularly preferably 1% by mass or less. The composition according to the embodiment of the present invention may contain only one kind of colorant, or may contain two or more kinds thereof. In a case where two or more kinds of colorants are contained, it is preferable that the total amount thereof is within the above-described range.

In addition, it is also preferable that the composition according to the embodiment of the present invention does not substantially contain the colorant. The case where the composition according to the embodiment of the present invention does not substantially contain the colorant means that the content of the colorant in the total solid content of the composition is 0.1% by mass or less, preferably 0.05% by mass or less and more preferably 0% by mass.

From the viewpoint of environmental regulation, the use of perfluoroalkyl sulfonic acid and a salt thereof and use of perfluoroalkyl carboxylic acid and a salt thereof may be restricted. In the composition, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the composition. The composition may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The composition may contain the perfluoroalkyl sulfonic acid and a salt thereof and the perfluoroalkyl carboxylic acid and a salt thereof within the maximum allowable range.

### <Storage Container>

A storage container of the composition according to the embodiment of the present invention is not particularly limited, and a well-known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A. In addition, for the purpose of preventing metal elution from the container interior wall, improving storage stability of the composition, and suppressing the alteration of components, it is also preferable that the container interior wall is formed of glass, stainless steel, or the like.

### <Manufacturing Method of Composition>

The composition according to the embodiment of the present invention can be produced by mixing the above-described components. During the production of the composition, all the components may be dissolved or dispersed in a solvent at the same time to produce the composition. Optionally, two or more solutions or dispersion liquids in which the respective components are appropriately blended may be prepared, and the solutions or dispersion liquids may be mixed with each other during use (during application) to produce the composition.

During the production of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components. In addition, the filter can be appropriately selected according to hydrophilicity or hydrophobicity of the composition.

### <Cured Film>

The cured film according to the embodiment of the present invention is a cured film formed of the above-described composition according to the embodiment of the present invention.

A refractive index of the cured film according to the embodiment of the present invention to light having a wavelength 633 nm is preferably 1.45 or less, more preferably 1.4 or less, still more preferably 1.35 or less, even more preferably 1.3 or less, and even still more preferably 1.27 or less. The above-described value of the refractive index is a value at a measurement temperature of 25° C.

It is preferable that the cured film according to the embodiment of the present invention has a sufficient hardness. In addition, the Young's modulus of the cured film is preferably 2 or more, more preferably 3 or more, and particularly preferably 4 or more. The upper limit value is preferably 10 or less.

A thickness of the cured film according to the embodiment of the present invention can be appropriately selected depending on the application. For example, the thickness of the film is preferably 3 μm or less, more preferably 1.5 μm or less, and particularly preferably 1.0 μm or less. The lower limit value is not particularly limited, but is preferably 50 nm or more.

The cured film according to the embodiment of the present invention can be used for an optical functional layer or the like in an image display device or a solid-state imaging element. Examples of the optically functional layer include an antireflection layer, a layer of low refractive index, and a waveguide.

The cured film according to the embodiment of the present invention can also be used as a member adjacent to a pixel of an optical filter having a plurality of pixels.

For example, the cured film according to the embodiment of the present invention can be used as a partition wall for separating pixels of an optical filter from each other. Examples of the pixel include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel. In addition, the cured film according to the embodiment of the present invention can also be used by being disposed on a light incidence side or a light emission side of an optical filter.

In addition, in a solid-state imaging element or an image display device having a microlens, the cured film according to the embodiment of the present invention can also be used by being formed on the microlens.

### <Manufacturing Method of Cured Film>

The manufacturing method of a cured film according to the embodiment of the present invention includes a step of applying the composition according to the embodiment of the present invention onto a support to form a composition layer; and

a step of subjecting the composition layer to a curing treatment,

in which a cured film in which the composition layer is cured is obtained at a temperature of 150° C. or lower throughout all the steps, and

the step of subjecting the composition layer to a curing treatment includes a step of generating an acid or a base from an acid generator or a base generator contained in the composition layer by performing light irradiation or heating on the composition layer.

The support for forming the composition layer is not particularly limited, and can be appropriately selected according to the use. Examples thereof include a substrate, for example, a wafer formed of a material such as silicon, non-alkali glass, soda glass, PYREX (registered trademark) glass, or quartz glass. In addition, it is also preferable to use an InGaAs substrate or the like. In addition, a charge coupled device (CCD), a complementary metal-oxide semiconductor (CMOS), a transparent conductive film, or the like may be formed on the support. In addition, a black matrix constituting of a light shielding material such as tungsten may be formed on the support. In addition, a base layer may be provided on the support so as to improve adhesiveness to an upper layer, prevent the diffusion of materials, or planarize the surface of the substrate. In addition, a microlens can also be used as the support.

As a method of applying the composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing method; a transfer method using molds and the like; and a nanoimprinting method. The application method using an ink jet method is not particularly limited, and examples thereof include a method (in particular, pp. 115 to 133) described in “Extension of Use of Ink Jet—Infinite Possibilities in Patent—” (published in February, 2005, S.B. Research Co., Ltd.) and methods described in JP2003-262716A, JP2003-185831A, JP2003-261827A, JP2012-126830A, and JP2006-169325A. In addition, with regard to the method for applying the composition for an optical sensor, reference can be made to the description in WO2017/030174A and WO2017/018419A, the contents of which are incorporated herein by reference.

The composition layer formed on the support may be dried (pre-baked). In a case where the pre-baking is performed, a pre-baking temperature is 150° C. or lower, preferably 120° C. or lower and more preferably 110° C. or lower. The lower limit is, for example, 50° C. or higher. The pre-baking time is preferably 10 to 300 seconds, more preferably 40 to 250 seconds, and still more preferably 80 to 220 seconds. The pre-baking can be performed using a hot plate, an oven, or the like.

In a case where a photoacid generator or a photobase generator is used as the generator in the composition according to the embodiment of the present invention, it is preferable that the above-described step of performing a curing treatment includes a step of performing exposure on the above-described composition layer by light irradiation.

Examples of the light which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

In a case where a photoacid generator or a photobase generator is used as the generator in the composition according to the embodiment of the present invention, it is preferable that the above-described step of performing a curing treatment includes a step of performing exposure on the above-described composition layer by light irradiation.

In a case where the thermal acid generator or the thermal base generator is used as the generator in the composition according to the embodiment of the present invention, it is preferable that the above-described step of performing the curing treatment includes a step of heating the above-described composition layer. A heating temperature is 150° C. or lower, preferably 120° C. or lower and more preferably 110° C. or lower. The lower limit is, for example, 80° C. or higher. A heating time is preferably 60 to 1800 seconds, more preferably 120 to 900 seconds, and still more preferably 180 to 600 seconds. The heating treatment can be performed using a hot plate, an oven, or the like. In a case where post-baking is performed during the formation of the composition layer, the post-baking may be a heating step in the curing treatment step. That is, during the post-baking, the composition layer may be dried, and an acid or a base may be generated from the thermal acid generator or the thermal base generator contained in the composition layer to perform the curing treatment of the composition layer.

An optical filter, an image display device, a solid-state imaging element, and the like can also be manufactured by applying the manufacturing method of a cured film according to the embodiment of the present invention.

### <Pattern Forming Method>

Next, a pattern forming method using the composition according to the embodiment of the present invention will be described. Examples of the pattern forming method include a pattern forming method by a photolithography method and a pattern forming method by an etching method.

The pattern formation by the photolithography method preferably includes a step of applying the composition according to the embodiment of the present invention onto a support to form a composition layer, a step of exposing the composition layer in a patterned manner, and a step of removing a non-exposed portion of the composition layer by development to form a pattern. A step of baking the composition layer (pre-baking step) and a step of baking the developed pattern (post-baking step) may be provided, as desired.

In the step of forming the composition layer, a composition layer is formed by applying the composition according to the embodiment of the present invention onto a support. Examples of the support include the above-described supports. In addition, examples of the method of applying the composition include the above-described application methods.

The composition layer formed on the support may be dried (pre-baked). In a case where the pre-baking is performed, a pre-baking temperature is 150° C. or lower, preferably 120° C. or lower and more preferably 110° C. or lower. The lower limit is, for example, 50° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the composition layer is exposed in a patterned manner (exposure step). For example, the composition layer can be exposed in a patterned manner using a stepper exposure device or a scanner exposure device through a mask having a predetermined mask pattern. Thus, the exposed portion can be cured.

Examples of the light which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

Next, the non-exposed portion of the composition layer is removed by development to form a pattern. The non-exposed portion of the composition layer can be removed by development using a developer. As a result, the composition layer of the non-exposed portion in the exposure step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkaline agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, an additional exposure treatment or a heating treatment (post-baking) may be performed after performing drying.

In a case where the post-baking is performed, a post-baking temperature is preferably 150° C. or lower. The upper limit of the post-baking temperature is more preferably 120° C. or lower and still more preferably 100° C. or lower. The lower limit of the post-baking temperature is not particularly limited as long as the curing of the film can be promoted, but is preferably 50° C. or higher and more preferably 75° C. or higher. A post-baking time is preferably 1 minute or more, more preferably 5 minutes or more, and still more preferably 10 minutes or more. The upper limit is not particularly limited, but from the viewpoint of productivity, 20 minutes or less is preferable.

In a case where the additional exposure treatment is performed, light used for the exposure is preferably light having a wavelength of 400 nm or less. In addition, the additional exposure treatment may be carried out by the method described in KR10-2017-0122130A.

The pattern formation by an etching method preferably includes a step of applying the composition according to the embodiment of the present invention onto a support to form a cured composition layer, which is the cured film according to the embodiment of the present invention, on the support using the above-described manufacturing method of a cured film according to the embodiment of the present invention; a step of forming a photoresist layer on the cured composition layer; a step of exposing the photoresist layer in a patterned manner and then developing the photoresist layer to form a resist pattern; a step of etching the cured composition layer through this resist pattern as a mask; and a step of peeling and removing the resist pattern from the cured composition layer.

A resist used for forming the resist pattern is not particularly limited. For example, a resist including an alkali-soluble phenol resin and naphthoquinone diazide described in pp. 16 to 22 of “Polymer New Material. One Point 3, Microfabrication and Resist, author: Saburo Nonogaki, Published by Kyoritsu Shuppan Co., Ltd. (First Edition, Nov. 15, 1987) can be used. In addition, a resist described in Examples and the like of JP2568883B, JP2761786B, JP2711590B, JP2987526B, JP3133881B, JP3501427B, JP3373072B, JP3361636B, or JP1994-054383A (JP-H06-054383A) can also be used. In addition, as the resist, a so-called chemically amplified resist can also be used. Examples of the chemically amplified resist include a resist described in p. 129 and later of “New Developments of Photo-functional Polymer Materials”, (May 31, 1996, first print, edited by Kunihiro Ichimura, published by CMC) (in particular, a resist including a polyhydroxystyrene resin in which a hydroxy group is protected by an acid-decomposable group that is described in about page 131 or an Environmentally Stable Chemical Amplification Positive (ESCAP) resist which is described in about page 131 is preferable). In addition, a resist described in, for example, Examples and the like of JP2008-268875A, JP2008-249890A, JP2009-244829A, JP2011-013581A, JP2011-232657A, JP2012-003070A, JP2012-003071A, JP3638068B, JP4006492B, JP4000407B, or JP4194249B can also be used.

A method of etching the cured composition layer may be a dry etching or a wet etching. A dry etching is preferable.

The dry etching of the cured composition layer is preferably performed by using a mixed gas of a fluorine-based gas and O₂ as an etching gas. The mixing ratio (fluorine-based gas/O₂) of the fluorine-based gas and O₂ is preferably 4/1 to 1/5, and more preferably 1/2 to 1/4 in terms of flow rate ratio. Examples of the fluorine-based gas include CF₄, C₂F₆, C₃F₈, C₂F₄, C₄F₈, C₄F₆, C₅F₈, and CHF₃, and C₄F₆, C₅F₈, C₄F₈, or CHF₃ is preferable, C₄F₆ or C₅F₈ is more preferable, and C₄F₆ is still more preferable. As the fluorine-based gas, one kind of gas can be selected from the above-described group, and two or more kinds thereof may be included in the mixed gas.

From the viewpoint of maintaining partial pressure control stability of the etching plasma and verticality of the specific etching shape, the above-described mixed gas may further be mixed with a rare gas such as helium (He), neon (Ne), argon (Ar), krypton (Kr), and xenon (Xe), in addition to the fluorine-based gas and O₂. As other gases which may be mixed, one kind or two or more kinds of gases can be selected from the above-described group. In a case where O₂ is set to be 1, the mixing ratio of the other gases which may be mixed is preferably more than 0 and 25 or less, preferably 10 to 20, and particularly preferably 16 in terms of flow rate ratio.

The internal pressure of a chamber during the dry etching is preferably 0.5 to 6.0 Pa, and more preferably 1 to 5 Pa.

Examples of dry etching conditions include conditions described in paragraphs 0102 to 0108 of WO2015/190374A, and JP2016-014856A, the contents of which are incorporated herein by reference.

### <Structural Body>

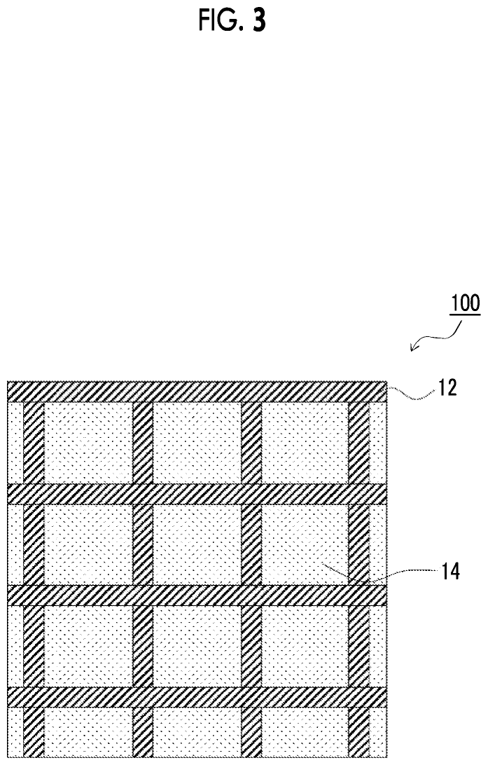

Next, the structural body according to an embodiment of the present invention will be described with reference to drawings. FIG. 2 is a side-sectional view showing an embodiment of the structural body according to the present invention, and FIG. 3 is a plan view of the structural body as viewed from directly above a support. As shown in FIGS. 2 and 3, a structural body 100 according to the embodiment of the present invention includes a support 11, a partition wall 12 provided on the support 11, and a pixel 14 provided on a region of the support 11 partitioned by the partition wall 12. Examples of the pixel include a colored pixel, a transparent pixel, a pixel of a near-infrared transmitting filter layer, and a pixel of a near-infrared cut filter layer. Examples of the colored pixel include a red pixel, a blue pixel, a green pixel, a yellow pixel, a cyan pixel, and a magenta pixel.

In the structural body according to the embodiment of the present invention, the type of the support 11 is not particularly limited. A substrate (silicon wafer, silicon carbide wafer, silicon nitride wafer, sapphire wafer, and glass wafer) used in various electronic devices such as a solid-state imaging element can be used. In addition, a substrate for a solid-state imaging element on which a photodiode is formed can also be used. In addition, as necessary, a base layer may be provided on these substrates so as to improve adhesiveness to an upper layer, prevent the diffusion of substances, or planarize the surface.

As shown in FIGS. 2 and 3, the partition wall 12 is formed on the support 11. In this embodiment, as shown in FIG. 3, the partition walls 12 are formed in a lattice form in a plan view seen from directly above the support 11. In this embodiment, the shape of the region partitioned by the partition wall 12 on the support 11 (hereinafter, also referred to as a shape of an opening portion of the partition wall) is a square shape, but the shape of the opening portion of the partition wall is not particularly limited, and may be, for example, a rectangular shape, a circular shape, an elliptical shape, a polygonal shape, or the like.

The partition wall 12 can be formed of the composition according to the embodiment of the present invention. Specifically, the partition wall 12 can be formed through a step of forming a composition layer using the composition according to the embodiment of the present invention, and a step of forming a pattern of the composition layer by a photolithography method or a dry etching method.

A width W1 of the partition wall 12 is preferably 20 to 500 nm. The lower limit is preferably 30 nm or more, more preferably 40 nm or more, and still more preferably 50 nm or more. The upper limit is preferably 300 nm or less, more preferably 200 nm or less, and still more preferably 100 nm or less.

In addition, a height H1 of the partition wall 12 is preferably 200 nm or more, more preferably 300 nm or more, and still more preferably 400 nm or more. The upper limit is preferably the thickness of the pixel 14 ×200% or less and more preferably the thickness of the pixel 14 ×150% or less, and it is still more preferable that the upper limit is substantially the same as the thickness of the pixel 14.

A height-to-width ratio (height/width) of the partition wall 12 is preferably 1 to 100, more preferably 5 to 50, and still more preferably 5 to 30.

The pixel 14 is formed in the region (opening portion of the partition wall) of the support 11 partitioned by the partition wall 12.

A width L1 of the pixel 14 can be appropriately selected depending on applications. For example, it is preferably 500 to 2000 nm, more preferably 500 to 1500 nm, and still more preferably 500 to 1000 nm.

A height (thickness) H2 of the pixel 14 can be appropriately selected depending on applications. For example, it is preferably 300 to 1000 nm, more preferably 300 to 800 nm, and still more preferably 300 to 600 nm. In addition, the height H2 of the pixel 14 is preferably 50% to 150% of the height H1 of the partition wall 12, more preferably 70% to 130% of the height H1 of the partition wall 12, and still more preferably 90% to 110% of the height H1 of the partition wall 12.

In the structural body according to the embodiment of the present invention, it is also preferable that a protective layer is provided on the surface of the partition wall. By providing the protective layer on the surface of the partition wall 12, adhesiveness between the partition wall 12 and the pixels 14 can be improved. As a material of the protective layer, various inorganic materials and organic materials can be used. Examples of the organic material include acrylic resin, polystyrene resin, polyimide resin, and organic spin on glass (SOG) resin. In addition, the protective layer can also be formed of a composition containing a compound having an ethylenically unsaturated bond-containing group.

The structural body according to the embodiment of the present invention can be preferably used for an optical filter, a solid-state imaging element, an image display device, and the like.

### <Optical Filter>

The optical filter according to an embodiment of the present invention has the cured film according to the embodiment of the present invention. Examples of the optical filter having the cured film according to the embodiment of the present invention include an optical filter having a structure in which each pixel is embedded in a region partitioned by a partition wall formed of the film according to the embodiment of the present invention. Examples of the pixel include a colored pixel, a transparent pixel, a pixel of a near-infrared transmitting filter layer, and a pixel of a near-infrared cut filter layer.

A width of the pixel included in the optical filter is preferably 0.4 to 10.0 μm. The lower limit is preferably 0.4 μm or more, more preferably 0.5 μm or more, and still more preferably 0.6 μm or more. The upper limit is preferably 5.0 μm or less, more preferably 2.0 μm or less, still more preferably 1.0 μm or less, and even more preferably 0.8 μm or less. In addition, a Young's modulus of the pixel is preferably 0.5 to 20 GPa and more preferably 2.5 to 15 GPa.

Each pixel included in the optical filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 500 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured using an ultra-high resistance meter 5410 (manufactured by Advantest Corporation).

A protective layer may be provided on a surface of the pixel in the optical filter. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method of forming the protective layer include a method of applying and forming a composition for forming a protective layer, a chemical vapor deposition method, and a method of attaching a molded resin with an adhesive material. In addition, as the protective layer, protective layers described in paragraphs 0073 to 0092 of JP2017-151176A can also be used.

### <Solid-State Imaging Element>

The solid-state imaging element according to the embodiment of the present invention includes the above-described cured film according to the embodiment of the present invention. The configuration of the solid-state imaging element is not particularly limited as long as it functions as a solid-state imaging element.

### <Image Display Device>

The cured film according to the embodiment of the present invention can also be used for an image display device. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

In addition, the organic electroluminescent display device may be a micro display. A diagonal length of a display surface in the micro display can be, for example, 4 inches or less, 2 inches or less, 1 inch or less, or 0.2 inches or less. The application of the micro display is not particularly limited, and examples thereof include an electronic view finder, smart glasses, and a head-mounted display.

The organic electroluminescent display device may be an organic electroluminescent display device which has a light source composed of a white organic electroluminescent element. It is preferable that the white organic electroluminescent element has a tandem structure. The tandem structure of the organic electroluminescent element is described in, for example, JP2003-045676A, or pp. 326 to 328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

The organic electroluminescent display device may have a color filter. The color filter may be provided on the base layer. In addition, in an organic electroluminescent display device of a system in which a color filter and a white organic electroluminescent element are combined to extract light of three primary colors, a transparent pixel may be provided to use white light as it is for light emission. In this manner, brightness of the display device can also be increased. In addition, the organic electroluminescent display device may have a lens on the color filter. As a shape of the lens, various shapes derived by an optical system design can be taken, and examples thereof include a convex shape and a concave shape. For example, by taking a concave shape (concave lens), it is easy to improve light collecting property. In addition, the lens may be in direct contact with the color filter, or another layer such as an adhesion layer and a planarizing layer may be provided between the lens and the color filter. In addition, the lens can also be disposed and used in the manner described in WO2018/135189A.

### Examples

Hereinafter, the present invention will be described in more detail with reference to the examples. Materials, used amounts, proportions, treatment details, treatment procedures, and the like shown in the following examples can be appropriately changed within a range not departing from the scope of the present invention. Therefore, the scope of the present invention is not limited to the specific examples described below.

### <Production of Composition>

Raw materials described in the following tables were mixed and filtered using a DFA4201NIEY (0.45 μm nylon filter) manufactured by Nihon Pall Corporation to produce a composition.

TABLE 1

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Example | P1 | 44.8 | Bead shape | B-1 | 0.4 | Photoacid | — |
| 1 | | | | | | generator | |
| Example | P2 | 44.8 | Hollow structure | B-1 | 0.4 | Photoacid | — |
| 2 | | | | | | generator | |
| Example | P1 | 44.8 | Bead shape | B-2 | 0.4 | Photobase | — |
| 3 | | | | | | generator | |
| Example | P2 | 44.8 | Hollow structure | B-2 | 0.4 | Photobase | — |
| 4 | | | | | | generator | |
| Example | P1 | 45 | Bead shape | B-1 | 0.2 | Photoacid | — |
| 5 | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example | — | — | — | F-1 | 0.2 | S-1 | 8 |
| 1 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | — | — | — | F-1 | 0.2 | S-1 | 8 |
| 2 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | — | — | — | F-1 | 0.2 | S-1 | 8 |
| 3 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | — | — | — | F-1 | 0.2 | S-1 | 8 |
| 4 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | — | — | — | F-1 | 0.2 | S-1 | 8 |
| 5 | | | | | | S-2 | 42.6 |
| | | | | | | S-3 | 0 |
| | | | | | | S-4 | 2 |
| | | | | | | S-5 | 1 |
| | | | | | | S-6 | 1 |

TABLE 2

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Example 6 | P1 | 44.4 | Bead shape | B-1 | 0.8 | Photoacid | — |
| | | | | | | generator | |
| Example 7 | P1 | 44 | Bead shape | B-1 | 1.2 | Photoacid | — |
| | | | | | | generator | |
| Example 8 | P1 | 44.8 | Bead shape | B-3 | 0.4 | Photoacid | — |
| | | | | | | generator | |
| Example 9 | P1 | 44.8 | Bead shape | B-4 | 0.4 | Photobase | — |
| | | | | | | generator | |
| Example | P1 | 44.8 | Bead shape | B-5 | 0.4 | Thermal | — |
| 10 | | | | | | acid | |
| | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example 6 | — | — | — | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 7 | — | — | — | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 8 | — | — | — | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 9 | — | — | — | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | — | — | — | F-1 | 0.2 | S-1 | 8 |
| 10 | | | | | | S-2 | 42.6 |
| | | | | | | S-3 | 0 |
| | | | | | | S-4 | 2 |
| | | | | | | S-5 | 1 |
| | | | | | | S-6 | 1 |

TABLE 3

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Example | P1 | 44.8 | Bead shape | B-6 | 0.4 | Thermal | — |
| 11 | | | | | | base | |
| | | | | | | generator | |
| Example | P1 | 43.8 | Bead shape | B-1 | 0.4 | Photoacid | C-1 |
| 12 | | | | | | generator | |
| Example | P1 | 43.8 | Bead shape | B-2 | 0.4 | Photobase | C-2 |
| 13 | | | | | | generator | |
| Example | P1 | 43.8 | Bead shape | B-2 | 0.4 | Photobase | C-3 |
| 14 | | | | | | generator | |
| Example | P1 | 42.8 | Bead shape | B-2 | 0.4 | Photobase | C-3 |
| 15 | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example | — | — | — | F-1 | 0.2 | S-1 | 8 |
| 11 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | 1.0 | — | — | F-1 | 0.2 | S-1 | 8 |
| 12 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | 1.0 | — | — | F-1 | 0.2 | S-1 | 8 |
| 13 | | | | | | S-2 | 42.6 |
| | | | | | | S-3 | 0 |
| | | | | | | S-4 | 2 |
| | | | | | | S-5 | 1 |
| | | | | | | S-6 | 1 |
| Example | 2.5 | — | — | F-1 | 0.2 | S-1 | 8 |
| 14 | | | | | | S-2 | 41.1 |
| | | | | | | S-3 | 0 |
| | | | | | | S-4 | 2 |
| | | | | | | S-5 | 1 |
| | | | | | | S-6 | 1 |
| Example | 5.0 | — | — | F-1 | 0.2 | S-1 | 8 |
| 15 | | | | | | S-2 | 39.6 |
| | | | | | | S-3 | 0 |
| | | | | | | S-4 | 2 |
| | | | | | | S-5 | 1 |
| | | | | | | S-6 | 1 |

TABLE 4

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Example 16 | P1 | 41.8 | Bead shape | B-2 | 0.4 | Photobase | C-3 |
| | | | | | | generator | |
| Example 17 | P1 | 44 | Bead shape | B-1 | 0.4 | Photoacid | — |
| | | | | | | generator | |
| Example 18 | P1 | 44 | Bead shape | B-2 | 0.4 | Photobase | — |
| | | | | | | generator | |
| Example 19 | P1 | 43.2 | Bead shape | B-2 | 0.4 | Photobase | — |
| | | | | | | generator | |
| Example 20 | P1 | 30 | Bead shape | B-2 | 1.2 | Photobase | C-3 |
| | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example 16 | 7.5 | — | — | F-1 | 0.2 | S-1 | 8 |
| | | | | | | S-2 | 38.1 |
| | | | | | | S-3 | 0 |
| | | | | | | S-4 | 2 |
| | | | | | | S-5 | 1 |
| | | | | | | S-6 | 1 |
| Example 17 | — | D-1 | 0.8 | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 18 | — | D-2 | 0.8 | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 19 | — | D-2 | 1.6 | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 20 | 7.5 | — | — | F-1 | 0.2 | S-1 | 8 |
| | | | | | | S-2 | 49.1 |
| | | | | | | S-3 | 0 |
| | | | | | | S-4 | 2 |
| | | | | | | S-5 | 1 |
| | | | | | | S-6 | 1 |

TABLE 5

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Example 21 | P3 | 44.8 | Planar shape | B-1 | 0.4 | Photoacid | — |
| | | | | | | generator | |
| Example 22 | P3 | 44.8 | Planar shape | B-2 | 0.4 | Photobase | — |
| | | | | | | generator | |
| Example 23 | P1 | 44.8 | Bead shape | B-1 | 0.4 | Photoacid | — |
| | | | | | | generator | |
| Example 24 | P1 | 44.8 | Bead shape | B-7 | 0.4 | Thermal | — |
| | | | | | | acid | |
| | | | | | | generator | |
| Example 25 | P2 | 22 | Hollow | B-7 | 1.2 | Thermal | C-3 |
| | | | structure | | | acid | |
| | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example 21 | — | — | — | F-1 | 0.2 | S-1 | 8 |
| | | | | | | S-2 | 43 |
| | | | | | | S-3 | 0 |
| | | | | | | S-4 | 2 |
| | | | | | | S-5 | 1 |
| | | | | | | S-6 | 1 |
| Example 22 | — | — | — | F-1 | 0.2 | S-1 | 8 |
| | | | | | | S-2 | 43 |
| | | | | | | S-3 | 0 |
| | | | | | | S-4 | 2 |
| | | | | | | S-5 | 1 |
| | | | | | | S-6 | 1 |
| Example 23 | — | — | — | F-2 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 24 | — | — | — | F-1 | 0.2 | S-1 | 8 |
| | | | | | | S-2 | 42.6 |
| | | | | | | S-3 | 0 |
| | | | | | | S-4 | 2 |
| | | | | | | S-5 | 1 |
| | | | | | | S-6 | 1 |
| Example 25 | 10.5 | — | — | F-1 | 0.2 | S-1 | 8 |
| | | | | | | S-2 | 54.1 |
| | | | | | | S-3 | 0 |
| | | | | | | S-4 | 2 |
| | | | | | | S-5 | 1 |
| | | | | | | S-6 | 1 |

TABLE 6

| | Silica particle solution | | | Acid generator or base generator | | | |
|---|---|---|---|---|---|---|---|
| | | Blending | | | Blending | | |
| | | amount | Shape of | | amount | | |
| | | (part by | silica | | (part by | | Resin |
| | Kind | mass) | particles | Kind | mass) | Type | Kind |
| Example 26 | P1 | 44.8 | Bead shape | B-2 | 0.5 | Photobase | — |
| | | | | | | generator | |
| Example 27 | P1 | 41.8 | Bead shape | B-2 | 0.5 | Photobase | — |
| | | | | | | generator | |
| Example 28 | P1 | 38.8 | Bead shape | B-2 | 0.5 | Photobase | — |
| | | | | | | generator | |
| Example 29 | P1 | 41.8 | Bead shape | B-2 | 1 | Photobase | — |
| | | | | | | generator | |
| Example 30 | P1 | 38.8 | Bead shape | B-2 | 1 | Photobase | — |
| | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example 26 | — | E-1 | 0.5 | F-1 | 0.1 | S-1 | 8 |
| | | | | | | S-2 | 42.1 |
| | | | | | | S-3 | 0 |
| | | | | | | S-4 | 2 |
| | | | | | | S-5 | 1 |
| | | | | | | S-6 | 1 |
| Example 27 | — | E-1 | 1 | F-1 | 0.1 | S-1 | 8 |
| | | | | | | S-2 | 44.6 |
| | | | | | | S-3 | 0 |
| | | | | | | S-4 | 2 |
| | | | | | | S-5 | 1 |
| | | | | | | S-6 | 1 |
| Example 28 | — | E-1 | 2 | F-1 | 0.1 | S-1 | 8 |
| | | | | | | S-2 | 46.6 |
| | | | | | | S-3 | 0 |
| | | | | | | S-4 | 2 |
| | | | | | | S-5 | 1 |
| | | | | | | S-6 | 1 |
| Example 29 | — | E-1 | 0.5 | F-1 | 0.1 | S-1 | 8 |
| | | | | | | S-2 | 44.6 |
| | | | | | | S-3 | 0 |
| | | | | | | S-4 | 2 |
| | | | | | | S-5 | 1 |
| | | | | | | S-6 | 1 |
| Example 30 | — | E-1 | 1 | F-1 | 0.1 | S-1 | 8 |
| | | | | | | S-2 | 46.6 |
| | | | | | | S-3 | 0 |
| | | | | | | S-4 | 2 |
| | | | | | | S-5 | 1 |
| | | | | | | S-6 | 1 |

TABLE 7

| | | | | Acid generator or base | | | |
|---|---|---|---|---|---|---|---|
| | Silica particle solution | | | generator | | | |
| | | Blending | | | Blending | | |
| | | amount | | | amount | | |
| | | (part by | Shape of silica | | (part by | | Resin |
| | Kind | mass) | particles | Kind | mass) | Type | Kind |
| Example | P1 | 34.7 | Bead shape | B-2 | (1 | Photobase | — |
| 31 | | | | | | generator | |
| Example | P1 | 38.8 | Bead shape | B-1 | 1 | Photobase | — |
| 32 | | | | | | generator | |
| Example | P1 | 38.8 | Bead shape | B-3 | 1 | Photobase | — |
| 33 | | | | | | generator | |
| Example | P1 | 38.8 | Bead shape | B-4 | 1 | Photobase | — |
| 34 | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example | — | E-1 | 2 | F-1 | 0.1 | S-1 | 8 |
| 31 | | | | | | S-2 | 50.2 |
| | | | | | | S-3 | 0 |
| | | | | | | S-4 | 2 |
| | | | | | | S-5 | 1 |
| | | | | | | S-6 | 1 |
| Example | — | E-1 | 1 | F-1 | 0.1 | S-1 | 8 |
| 32 | | | | | | S-2 | 46.6 |
| | | | | | | S-3 | 0 |
| | | | | | | S-4 | 2 |
| | | | | | | S-5 | 1 |
| | | | | | | S-6 | 1 |
| Example | — | E-1 | 1 | F-1 | 0.1 | S-1 | 8 |
| 33 | | | | | | S-2 | 46.6 |
| | | | | | | S-3 | 0 |
| | | | | | | S-4 | 2 |
| | | | | | | S-5 | 1 |
| | | | | | | S-6 | 1 |
| Example | — | E-1 | 1 | F-1 | 0.1 | S-1 | 8 |
| 34 | | | | | | S-2 | 46.6 |
| | | | | | | S-3 | 0 |
| | | | | | | S-4 | 2 |
| | | | | | | S-5 | 1 |
| | | | | | | S-6 | 1 |

TABLE 8

| | | | | Acid generator or base | | | |
|---|---|---|---|---|---|---|---|
| | Silica particle solution | | | generator | | | |
| | | Blending | | | Blending | | |
| | | amount | | | amount | | |
| | | (part by | Shape of silica | | (part by | | Resin |
| | Kind | mass) | particles | Kind | mass) | Type | Kind |
| Example | P1 | 38.8 | Bead shape | B-2 | 1 | Photobase | — |
| 35 | | | | | | generator | |
| Example | P1 | 38.8 | Bead shape | B-2 | 1 | Photobase | — |
| 36 | | | | | | generator | |
| Example | P1 | 38.8 | Bead shape | B-2 | 1 | Photobase | — |
| 37 | | | | | | generator | |
| Example | P1 | 38.8 | Bead shape | B-2 | 1 | Photobase | — |
| 38 | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Example | — | E-2 | 1 | F-1 | 0.1 | S-1 | 8 |
| 35 | | | | | | S-2 | 46.6 |
| | | | | | | S-3 | 0 |
| | | | | | | S-4 | 2 |
| | | | | | | S-5 | 1 |
| | | | | | | S-6 | 1 |
| Example | — | E-3 | 1 | F-1 | 0.1 | S-1 | 8 |
| 36 | | | | | | S-2 | 46.6 |
| | | | | | | S-3 | 0 |
| | | | | | | S-4 | 2 |
| | | | | | | S-5 | 1 |
| | | | | | | S-6 | 1 |
| Example | — | E-4 | 1 | F-1 | 0.1 | S-1 | 8 |
| 37 | | | | | | S-2 | 44.6 |
| | | | | | | S-3 | 0 |
| | | | | | | S-4 | 2 |
| | | | | | | S-5 | 1 |
| | | | | | | S-6 | 1 |
| Example | — | E-5 | 1 | F-1 | 0.1 | S-1 | 8 |
| 38 | | | | | | S-2 | 44.6 |
| | | | | | | S-3 | 0 |
| | | | | | | S-4 | 2 |
| | | | | | | S-5 | 1 |
| | | | | | | S-6 | 1 |

TABLE 9

| | Silica particle solution | | | Acid generator or base generator | | | |
|---|---|---|---|---|---|---|---|
| | | Blending | | | Blending | | |
| | | amount | | | amount | | |
| | | (part by | Shape of silica | | (part by | | Resin |
| | Kind | mass) | particles | Kind | mass) | Type | Kind |
| Comparative | P3 | 44.8 | Planar shape | — | — | — | — |
| Example 1 | | | | | | | |
| Comparative | P2 | 20 | Hollow | B-7 | 0.3 | Thermal | C-3 |
| Example 2 | | | structure | | | acid | |
| | | | | | | generator | |

| | Resin | Silanol compound | | Surfactant | | Solvent | |
|---|---|---|---|---|---|---|---|
| | Blending | | Blending | | Blending | | Blending |
| | amount | | amount | | amount | | amount |
| | (part by | | (part by | | (part by | | (part by |
| | mass) | Kind | mass) | Kind | mass) | Kind | mass) |
| Comparative | — | — | — | F-1 | 0.2 | S-1 | 8 |
| Example 1 | | | | | | S-2 | 43 |
| | | | | | | S-3 | 0 |
| | | | | | | S-4 | 2 |
| | | | | | | S-5 | 1 |
| | | | | | | S-6 | 1 |
| Comparative | 14.0 | — | — | F-1 | 0.2 | S-1 | 8 |
| Example 2 | | | | | | S-2 | 53.5 |
| | | | | | | S-3 | 0 |
| | | | | | | S-4 | 2 |
| | | | | | | S-5 | 1 |
| | | | | | | S-6 | 1 |

Among the raw materials listed in the above tables, details of the raw materials shown by abbreviations are as follows.

### [Silica Particle Solution]

P1: propylene glycol monomethyl ether solution of silica particles (beaded silica) having a shape in which a plurality of spherical silicas having an average particle diameter of 15 nm are connected in a bead shape by metal oxide-containing silica (connecting material) (concentration of silica particles: 20% by mass)
P2: THRULYA 4110 (manufactured by JGC C&C, solution of silica particles having a hollow structure with an average particle diameter of 60 nm, concentration of silica particles: 20% by mass; the silica particle solution does not include both the silica particles in which a plurality of spherical silica particles are connected in a bead shape and the silica particles in which a plurality of spherical silicas are connected in a planar shape)
P3: MIBK-ST (manufactured by Nissan Chemical Corporation, solution of solid silica particles with an average particle diameter of 15 nm, concentration of silica particles: 20% by mass; the silica particle solution does not include all of the silica particles in which a plurality of spherical silica particles are connected in a bead shape, the silica particles in which a plurality of spherical silicas are connected in a planar shape, and the silica particles having a hollow structure)

All of the silica particles contained in the silica particle solutions P1 to P3 are particles having a silanol group.

In addition, as the average particle diameter of the spherical silica in the silica particle solution P1, the number average of circle-equivalent diameters in a projection image of the spherical portions of 50 spherical silicas measured by a transmission electron microscope (TEM) was calculated and obtained. In addition, in the silica particle solution P1, by a method of TEM observation, it was investigated whether or not the silica particle solution included silica particles having a shape in which a plurality of spherical silicas were connected in a beaded shape.

### [Acid Generator and Base Generator]

B-1: IRGACURE PAG-103 (manufactured by BASF SE, compound having the following structure, oxime sulfonate compound, photoacid generator)

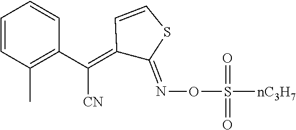

B-2: WPBG-018 (manufactured by FUJIFILM Wako Pure Chemical Corporation, compound having the following structure, carbamate compound, photobase generator)

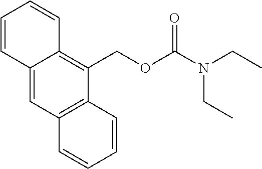 [SMILES: CCN(CC)C(=O)OCc1c2ccccc2cc2ccccc12]

B-3: MOP-triazine (manufactured by Sanwa Chemical Co., Ltd., compound having the following structure, triazine compound, photoacid generator)

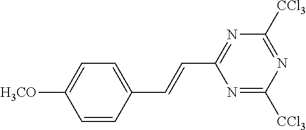

B-4: WPBG-165 (manufactured by FUJIFILM Wako Pure Chemical Corporation, compound having the following structure, carbamate compound, photobase generator)

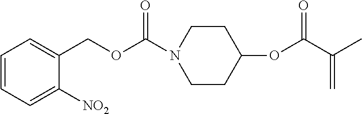 [SMILES: C=C(C)C(=O)OC1CCN(C(=O)OCc2ccccc2[N+](=O)[O-])CC1]

B-5: SAN-AID SI-60 (manufactured by SANSHIN CHEMICAL INDUSTRY CO., LTD., SbF₆⁻-based sulfonium salt, thermal acid generator)
B-6: U-CAT SA1 (manufactured by San-Apro Ltd., compound having the following structure, quaternary ammonium salt, thermal base generator)

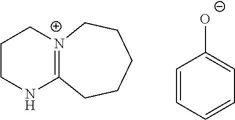 [SMILES: C1CCC2=[N+](CC1)CCCN2 ; [O-]c1ccccc1]

B-7: SI-106 (manufactured by Midori Kagaku Co., Ltd., N-(camphorsulfonyloxy)succinimide, sulfonimide compound, thermal acid generator)

### [Resin]

C-1: SILAPLANE FM-DA21 (manufactured by JNC Corporation, number-average molecular weight: 5,000, resin having the following structure)

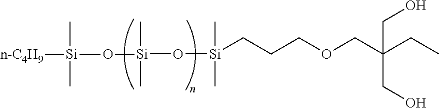

C-2: SILAPLANE FM-3321 (manufactured by JNC Corporation, number-average molecular weight: 5,000, resin having the following structure)

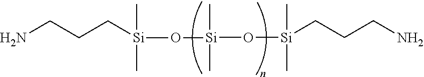

C-3: polysiloxane resin solution produced by the following method

74.23 μg (0.55 mol) of methyltrimethoxysilane, 69.41 g (0.35 mol) of phenyltrimethoxysilane, 21.82 g (0.1 mol) of trifluoropropyltrimethoxysilane, and 132.4 g of diacetone alcohol were charged into an 500 mL three-neck flask, and a phosphoric acid aqueous solution which had been prepared by dissolving 0.319 g of phosphoric acid in 52.02 g of water was added thereto over 30 minutes while stirring at room temperature. Thereafter, the flask was immersed in an oil bath at 40° C. and stirred for 30 minutes, and the oil bath was heated to 115° C. over 30 minutes. One hour after the start of the temperature elevation, the internal temperature of the solution reached 100° C., and then the solution was heated and stirred for 35 minutes (internal temperature: 100° C. to 110° C.). Diacetone alcohol was added to the obtained diacetone alcohol solution of the polysiloxane resin such that the concentration of polysiloxane was 40% by mass, thereby obtaining a polysiloxane resin solution. A weight-average molecular weight of the obtained polysiloxane resin was 4,300.

### [Silanol Compound]

D-1: X-12-1135 (manufactured by Shin-Etsu Chemical Co., Ltd., compound having a molecular weight of 1,000 or less)
D-2: KBP-90 (manufactured by Shin-Etsu Chemical Co., Ltd., compound having a molecular weight of 1,000 or less)

### [Silane Coupling Agent]

E-1: KBM-503 (manufactured by Shin-Etsu Chemical Co., Ltd., compound having the following structure, compound having an alkoxysilyl group)
E-2: KBM-4803 (manufactured by Shin-Etsu Chemical Co., Ltd., compound having the following structure, compound having an alkoxysilyl group)
E-3: KBM-3086 (manufactured by Shin-Etsu Chemical Co., Ltd., compound having the following structure, compound having an alkoxysilyl group)
E-4: KBM-9659 (manufactured by Shin-Etsu Chemical Co., Ltd., compound having the following structure, compound having an alkoxysilyl group)
E-5: X-12-5263HP (manufactured by Shin-Etsu Chemical Co., Ltd., compound having the following structure, compound having an alkoxysilyl group)

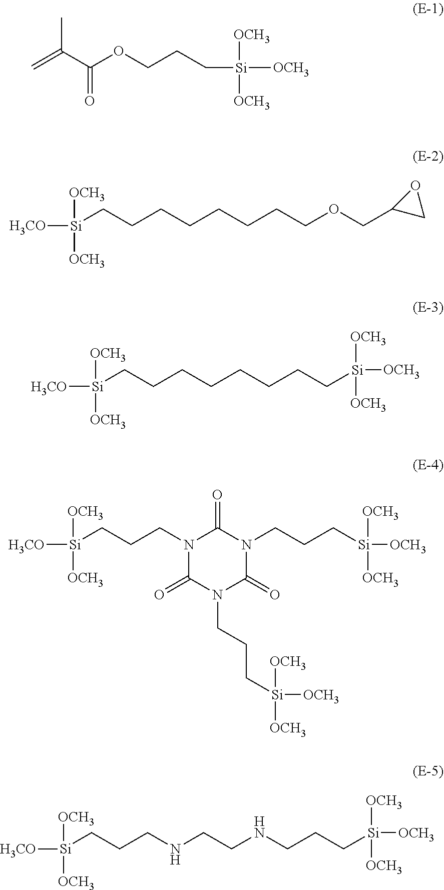 [SMILES: C=C(C)C(=O)OCCC[Si](OC)(OC)OC ; CO[Si](CCCCCCCCOCC1CO1)(OC)OC ; CO[Si](CCCCCCCC[Si](OC)(OC)OC)(OC)OC ; CO[Si](CCCn1c(=O)n(CCC[Si](OC)(OC)OC)c(=O)n(CCC[Si](OC)(OC)OC)c1=O)(OC)OC ; CO[Si](CCCNCCNCCC[Si](OC)(OC)OC)(OC)OC]

### [Surfactant]

F-1: compound having the following structure (silicone-based surfactant, carbinol-modified silicone compound, weight-average molecular weight: 3,000, kinematic viscosity at 25° C.: 45 mm²/s)

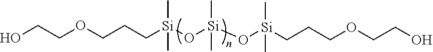

F-2: compound having the following structure (fluorine-based surfactant, weight-average molecular weight=14,000; a numerical value “%” representing the proportion of a repeating unit is mol %)

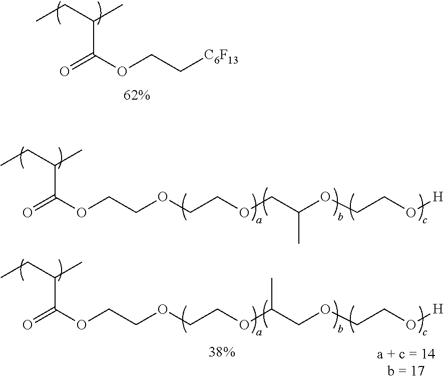

### [Solvent]

S-1: 1,4-butanediol diacetate (boiling point: 232° C., viscosity: 3.1 mPa·s, molecular weight: 174)
S-2: propylene glycol monomethyl ether acetate (boiling point: 146° C., viscosity: 1.1 mPa·s, molecular weight: 132)
S-3: propylene glycol monomethyl ether (boiling point: 120° C., viscosity: 1.8 mPa·s, molecular weight: 90)
S-4: methanol (boiling point: 64° C., viscosity: 0.6 mPa·s)
S-5: ethanol (boiling point: 78° C., viscosity: 1.2 mPa·s)
S-6: water (boiling point: 100° C., viscosity: 0.9 mPa·s)

### <Evaluation of Refractive Index>

Each composition of Examples 1 to 9 and 12 to 23 was applied onto an 8-inch (20.32 cm) silicon wafer by a spin coating method such that a film thickness after the application was 0.4 μm. Next, using an ultra-high pressure mercury lamp, the coating film was exposed to light under conditions of an exposure illuminance of 20 mW/cm² and an exposure amount of 1000 mJ/cm². Next, the coating film was heated on a hot plate at 100° C. for 20 minutes, and allowed to cool to form a cured film.

The composition of Examples 10, 11, 24, and 25 and Comparative Examples 1 and 2 was applied onto an 8-inch (20.32 cm) silicon wafer by a spin coating method such that a film thickness after the application was 0.4 μm. Next, the coating film was heated on a hot plate at 100° C. for 20 minutes, and allowed to cool to form a cured film.

The refractive index of the obtained cured film to light having a wavelength of 633 nm was measured (measurement temperature: 25° C.) using an ellipsometer (VUV-vase, manufactured by J.A. Woollam), and the refractive index was evaluated according to the following standard.
5: refractive index was 1.300 or less.
4: refractive index was more than 1.300 and 1.350 or less.
3: refractive index was more than 1.350 and 1.400 or less.
2: refractive index was more than 1.400 and 1.450 or less.
1: refractive index was more than 1.450.

### <Evaluation of Moisture Resistance>

Each composition of Examples 1 to 9, 12 to 23, and 26 to 38 was applied onto an 8-inch (20.32 cm) silicon wafer by a spin coating method such that a film thickness after the application was 0.4 μm. Next, using an ultra-high pressure mercury lamp, the coating film was exposed to light under conditions of an exposure illuminance of 20 mW/cm² and an exposure amount of 1000 mJ/cm². Next, the coating film was heated on a hot plate at 100° C. for 20 minutes, and allowed to cool to form a cured film.

The composition of Examples 10, 11, 24, and 25 and Comparative Examples 1 and 2 was applied onto an 8-inch (20.32 cm) silicon wafer by a spin coating method such that a film thickness after the application was 0.4 μm. Next, the coating film was heated on a hot plate at 100° C. for 20 minutes, and allowed to cool to form a cured film.

The obtained cured film was subjected to a humidity test for 168 hours under the conditions of a temperature of 130° C. and a humidity of 85% using a highly accelerated life test device (manufactured by ESPEC CORP., EHS-212). The refractive index of the cured film before and after the humidity test to light having a wavelength of 633 nm was measured (measurement temperature: 25° C.) using an ellipsometer (VUV-vase, manufactured by J.A. Woollam), an amount of change in refractive index of the cured film before and after the humidity test was calculated, and the moisture resistance was evaluated according to the following standard.

Amount of change in refractive index=|Refractive index of cured film before moisture resistance test−Refractive index of cured film after moisture resistance test|
5: amount of change in refractive index was 0.005 or less.
4: amount of change in refractive index was more than 0.005 and 0.010 or less.
3: amount of change in refractive index was more than 0.010 and 0.020 or less.
2: amount of change in refractive index was more than 0.020 and 0.030 or less.
1: amount of change in refractive index was more than 0.030.

The evaluation results are shown in the following table. In addition, in the following table, the content of the silica particles in the total solid content of the composition is described in the column of “Content of silica particles”. In addition, the content of the acid generator or the base generator in the total solid content of the composition is described in the column of “Content of acid generator or base generator”.

TABLE 10

| | | | | Content of acid |
|---|---|---|---|---|
| | Performance evaluation | | Content of | generator or |
| | Refractive | Moisture | silica particles | base generator |
| | index | resistance | (% by mass) | (% by mass) |
| Example 1 | 5 | 5 | 93.7 | 4.2 |
| Example 2 | 4 | 4 | 93.7 | 4.2 |
| Example 3 | 5 | 5 | 93.7 | 4.2 |
| Example 4 | 4 | 4 | 93.7 | 4.2 |
| Example 5 | 5 | 4 | 95.7 | 2.1 |
| Example 6 | 4 | 5 | 89.9 | 8.1 |
| Example 7 | 3 | 4 | 86.3 | 11.8 |
| Example 8 | 5 | 5 | 93.7 | 4.2 |
| Example 9 | 5 | 5 | 93.7 | 4.2 |
| Example 10 | 5 | 5 | 93.7 | 4.2 |
| Example 11 | 5 | 5 | 93.7 | 4.2 |
| Example 12 | 3 | 4 | 84.6 | 3.9 |
| Example 13 | 3 | 4 | 84.6 | 3.9 |
| Example 14 | 4 | 4 | 84.6 | 3.9 |
| Example 15 | 3 | 3 | 76.7 | 3.6 |
| Example 16 | 3 | 2 | 69.9 | 3.3 |
| Example 17 | 4 | 5 | 86.3 | 3.9 |
| Example 18 | 4 | 5 | 86.3 | 3.9 |
| Example 19 | 3 | 5 | 79.7 | 3.7 |
| Example 20 | 2 | 3 | 57.7 | 11.5 |
| Example 21 | 1 | 3 | 93.7 | 4.2 |
| Example 22 | 1 | 3 | 93.7 | 4.2 |
| Example 23 | 5 | 5 | 93.7 | 4.2 |
| Example 24 | 5 | 5 | 93.7 | 4.2 |
| Example 25 | 2 | 2 | 44.0 | 12.0 |
| Example 26 | 4 | 5 | 89.1 | 5.0 |
| Example 27 | 4 | 5 | 83.9 | 5.0 |
| Example 28 | 3 | 5 | 74.9 | 4.8 |
| Example 29 | 4 | 5 | 83.9 | 10.0 |
| Example 30 | 3 | 5 | 78.7 | 10.1 |
| Example 31 | 3 | 5 | 69.1 | 10.0 |
| Example 32 | 3 | 5 | 78.7 | 10.1 |
| Example 33 | 3 | 5 | 78.7 | 10.1 |
| Example 34 | 3 | 5 | 78.7 | 10.1 |
| Example 35 | 3 | 5 | 78.7 | 10.1 |
| Example 36 | 3 | 5 | 78.7 | 10.1 |
| Example 37 | 3 | 5 | 78.7 | 10.1 |
| Example 38 | 3 | 5 | 78.7 | 10.1 |
| Comparative | 1 | 1 | 97.8 | 0 |
| Example 1 | | | | |
| Comparative | 1 | 1 | 39.6 | 3.0 |
| Example 2 | | | | |

As shown in the above table, in all of Examples, it was possible to form a cured film having suppressed moisture resistance as compared with Comparative Examples.

The composition of Examples 26 to 38 was applied onto an 8-inch silicon wafer by a spin coating method such that a film thickness after the application was 0.4 μm, and then using an i-ray stepper exposure device FPA-3000 i5+ (manufactured by Canon Inc.), the coating film was exposed to light through a mask with an island pattern opening of 100 μm×100 μm. Next, puddle development was performed at 23° C. for 60 seconds using a 2.38% by mass tetramethylammonium hydroxide aqueous solution. Next, the coating film was rinsed by spin showering and was cleaned with pure water. Next, in a case where the coating film was heated on a hot plate at 100° C. for 15 minutes and allowed to cool to form an island pattern of 100 μm×100 μm, a good pattern could be formed.

### <Manufacturing of Color Filter>

The composition of Example 1 was applied onto a surface of an 8-inch (20.32 cm) silicon wafer by a spin coating method, heated (pre-baked) using a hot plate at 90° C. for 120 seconds, irradiated with light at an exposure amount of 1000 mJ/cm² using an i-ray stepper exposure device FPA-3000 i5+ (manufactured by Canon Inc.), and heated (post-baked) at 100° C. for 1200 seconds, thereby forming a partition wall material layer having a film thickness of 1.2 m. A positive type photoresist for KrF was applied onto the partition wall material layer with a spin coater, and a heating treatment was performed at 100° C. for 2 minutes to form a photoresist layer having a film thickness of 1.0 μm. Next, the corresponding region was exposed in a patterned manner with an exposure amount of 30 mJ/cm², and then heat-treated at 110° C. for 1 minute. Thereafter, a development treatment was performed with a developer for 1 minute, and then a post-baking treatment was performed at 100° C. for 1 minute to remove a photoresist in a region where partition walls were to be formed. Next, the partition wall material layer was treated under the following dry etching conditions, and partition walls having a width of 0.6 μm were formed in a lattice form with a pitch width of 3.6 μm. A width of the partition wall opening portion was 3.0 μm. The pitch width of the partition wall is the total of the width of the opening portion of the partition wall and the width of the partition wall.

### —Dry Etching Conditions—

Equipment used: U-621 manufactured by Hitachi High-Tech Corporation

### Pressure: 2.0 Pa

Gas used: Ar/C4F6/O2=1000/20/50 mL/min
Treatment temperature: 20° C.
Source power: 500 W
Upper bias/electrode bias=500/1000 W
Treatment time: 220 sec

Next, a coloring composition for forming a green pixel was applied onto the surface of the silicon wafer on which the partition walls were formed and the surfaces of the partition walls by a spin coating method such that a film thickness after film formation was 1.2 μm. Next, the coating film was heated using a hot plate at 90° C. for 120 seconds. Next, using an i-ray stepper exposure device FPA-3000 i5+ (manufactured by Canon Inc.), the silicon wafer was exposed to light through a mask having a pattern at an exposure amount of 200 mJ/cm². Next, puddle development was performed at 23° C. for 60 seconds using a 0.3% by mass tetramethylammonium hydroxide aqueous solution. Next, the coating film was rinsed by spin showering and was cleaned with pure water. Next, the coating film was heated using a hot plate at 100° C. for 900 seconds to form a green-colored pattern (green pixel). In the same manner, a coloring composition for forming a red pixel and a coloring composition for forming a blue pixel were sequentially patterned to form a red-colored pattern (red pixel) and a blue-colored pattern (blue pixel), respectively, thereby forming a color filter.

As the coloring composition for forming a green pixel, a coloring composition 1 for forming a green pixel, a coloring composition 2 for forming a green pixel, or a coloring composition 3 for forming a green pixel, which are described below, was used. As the coloring composition for forming a red pixel, a coloring composition 1 for forming a red pixel or a coloring composition 2 for forming a red pixel, which are described below, was used. As the coloring composition for forming a blue pixel, a coloring composition 1 for forming a blue pixel, which is described below, was used.

The obtained color filter was incorporated into an organic electroluminescent display device according to a known method. This organic electroluminescent display device had a suitable image recognition ability.

### (Coloring Composition 1 for Forming Green Pixel)

The following components were mixed and stirred, and the obtained mixture was filtered through a nylon filter (manufactured by Nihon Pall Corporation) having a pore size of 0.45 μm to prepare the coloring composition 1 for forming a green pixel.

Green pigment dispersion liquid . . . 76.80 parts by mass
Photopolymerization initiator 1 . . . 0.97 parts by mass
Photopolymerization initiator 2 . . . 0.58 parts by mass
Resin solution 1 . . . 1.57 parts by mass
Polymerizable compound 1 . . . 0.97 parts by mass
Polymerizable compound 2 . . . 0.97 parts by mass
Surfactant 1 . . . 0.001 parts by mass
Cyclohexanone . . . 18.14 parts by mass

### (Coloring Composition 2 for Forming Green Pixel)

The coloring composition 2 for forming a green pixel was prepared in the same manner as in the coloring composition 1 for forming a green pixel, except that the green pigment dispersion liquid 1 of the coloring composition 1 for forming a green pixel was changed to a green pigment dispersion liquid 2.

### (Coloring Composition 3 for Forming Green Pixel)

The coloring composition 3 for forming a green pixel was prepared in the same manner as in the coloring composition 1 for forming a green pixel, except that the green pigment dispersion liquid 1 of the coloring composition 1 for forming a green pixel was changed to a green pigment dispersion liquid 3.

### (Coloring Composition 1 for Forming Red Pixel)

The following components were mixed and stirred, and the obtained mixture was filtered through a nylon filter (manufactured by Nihon Pall Corporation) having a pore size of 0.45 μm to prepare the coloring composition 1 for forming a red pixel.

Red pigment dispersion liquid 1 . . . 60.31 parts by mass
Photopolymerization initiator 1 . . . 0.83 parts by mass
Photopolymerization initiator 2 . . . 0.58 parts by mass
Resin solution 1 . . . 3.26 parts by mass
Polymerizable compound 1 . . . 0.83 parts by mass
Polymerizable compound 2 . . . 0.83 parts by mass
Surfactant 1 . . . 0.004 parts by mass
Propylene glycol monomethyl ether . . . 16.68 parts by mass
Cyclopentanone . . . 16.68 parts by mass

### (Coloring Composition 2 for Forming Red Pixel)

The coloring composition 2 for forming a red pixel was prepared in the same manner as in the coloring composition 1 for forming a red pixel, except that the red pigment dispersion liquid 1 of the coloring composition 1 for forming a red pixel was changed to a red pigment dispersion liquid 2.

### (Coloring Composition 1 for Forming Blue Pixel)

The following components were mixed and stirred, and the obtained mixture was filtered through a nylon filter (manufactured by Nihon Pall Corporation) having a pore size of 0.45 μm to prepare the coloring composition 1 for forming a blue pixel.

Blue pigment dispersion liquid 1 . . . 56.7 parts by mass
Violet dye solution 1 . . . 16.28 parts by mass
Photopolymerization initiator 3 . . . 1.19 parts by mass
Photopolymerization initiator 2 . . . 0.64 parts by mass
Resin solution 1 . . . 0.93 parts by mass
Polymerizable compound 3 . . . 2.97 parts by mass
Epoxy compound 1 . . . 1.40 parts by mass
Surfactant 1 . . . 0.006 parts by mass
Cyclohexanone . . . 19.89 parts by mass

Materials used for each coloring composition for forming a pixel are as follows.

### Green Pigment Dispersion Liquid 1: Green Pigment Dispersion Liquid 1 Prepared by the Following Method

A mixed solution consisting of 7.59 parts by mass of C. I. Pigment Green 36, 4.41 parts by mass of C. I. Pigment Yellow 185, 1.33 parts by mass of a pigment derivative 1, 6.77 parts by mass of a dispersant 1, and 80.00 parts by mass of propylene glycol monomethyl ether acetate (PGMEA) was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the green pigment dispersion liquid 1.

Pigment derivative 1: compound having the following structure

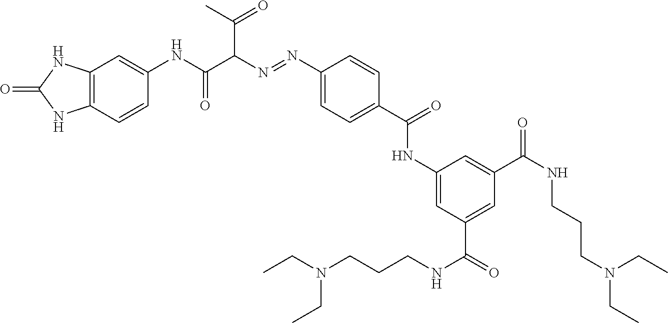 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant 1: resin having the following structure (a numerical value in parentheses of a main chain represents a molar ratio of each repeating unit, and a numerical value in parentheses of a side chain represents the repetition number of the repeating unit; weight-average molecular weight: 20,000)

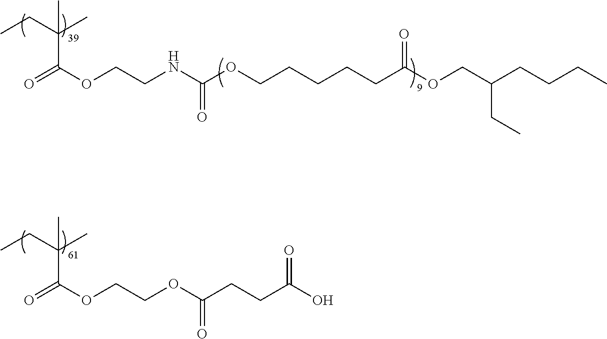

### Green Pigment Dispersion Liquid 2: Green Pigment Dispersion Liquid 2 Prepared by the Following Method

A mixed solution consisting of 1.31 parts by mass of C. I. Pigment Green 36, 3.03 parts by mass of C. I. Pigment Green 7, 1.24 parts by mass of C. I. Pigment Blue 15:4, 2.32 parts by mass of C. I. Pigment Yellow 185, 0.35 parts by mass of C. I. Pigment Yellow 150, 3.74 parts by mass of C. I. Pigment Yellow 139, 1.33 parts by mass of the pigment derivative 1, 6.77 parts by mass of the dispersant 1, and 80.00 parts by mass of PGMEA was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the green pigment dispersion liquid 2.

### Green Pigment Dispersion Liquid 3: Green Pigment Dispersion Liquid 3 Prepared by the Following Method

A mixed solution consisting of 5.81 parts by mass of C. I. Pigment Green 36, 1.64 parts by mass of C. I. Pigment Blue 15:4, 1.94 parts by mass of C. I. Pigment Yellow 185, 2.61 parts by mass of C. I. Pigment Yellow 139, 1.33 parts by mass of the pigment derivative 1, 6.77 parts by mass of the dispersant 1, and 80.00 parts by mass of PGMEA was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the green pigment dispersion liquid 3.

### Red Pigment Dispersion Liquid 1: Red Pigment Dispersion Liquid 1 Prepared by the Following Method

A mixed solution consisting of 10.68 parts by mass of C. I. Pigment Red 254, 2.82 parts by mass of C. I. Pigment Yellow 139, 1.50 parts by mass of the pigment derivative 1, 5.25 parts by mass of the dispersant 1, and 80.00 parts by mass of PGMEA was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the red pigment dispersion liquid 1.

### Red Pigment Dispersion Liquid 2: Red Pigment Dispersion Liquid 2 Prepared by the Following Method

A mixed solution consisting of 10.68 parts by mass of C. I. Pigment Red 264, 2.82 parts by mass of C. I. Pigment Yellow 139, 1.50 parts by mass of the pigment derivative 1, 5.25 parts by mass of the dispersant 1, and 80.00 parts by mass of PGMEA was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the red pigment dispersion liquid 2.

### Blue Pigment Dispersion Liquid 1: Blue Pigment Dispersion Liquid 1 Prepared by the Following Method

A mixed solution consisting of 10.00 parts by mass of C. I. Pigment Blue 15:6, 3.50 parts by mass of a dispersant 2, and 86.50 parts by mass of PGMEA was mixed and dispersed for 3 hours using a beads mill (zirconia beads with a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. This dispersion treatment was repeated 10 times to the blue pigment dispersion liquid 1.

Dispersant 2: resin having the following structure (a numerical value in parentheses of a main chain represents a molar ratio of each repeating unit; weight-average molecular weight: 11,000)

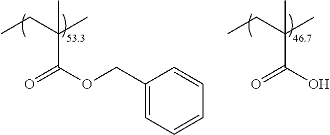

Violet dye solution 1: 20% by mass cyclohexanone solution of a dye having the following structure (in the structural formula shown below, iPr is an isopropyl group)

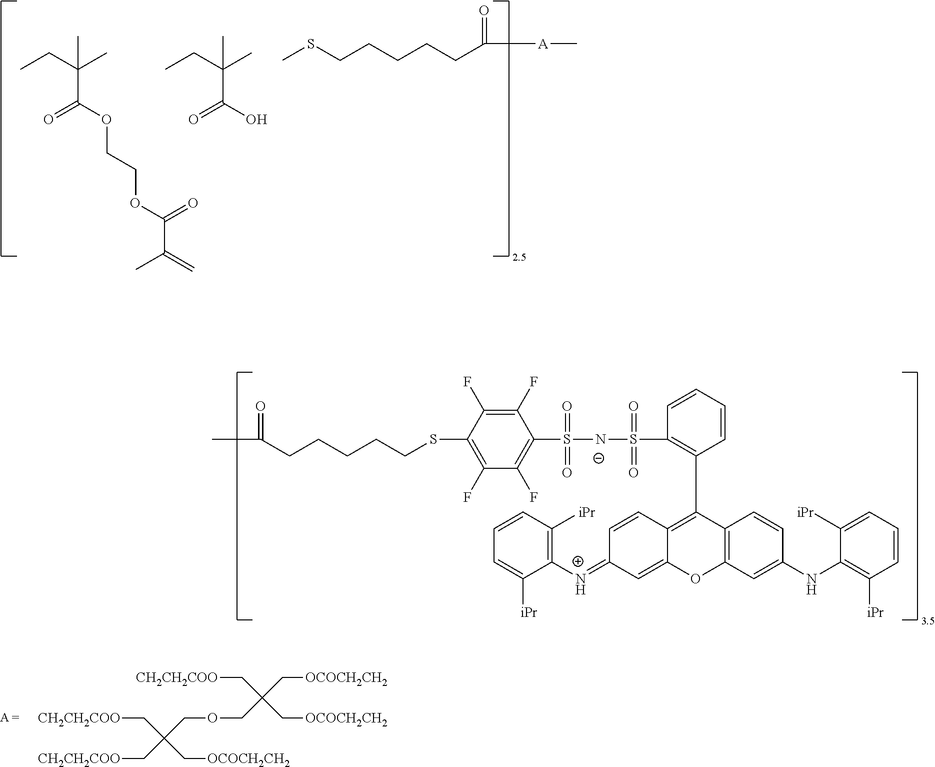

Photopolymerization initiator 1: Irgacure OXE03 (manufactured by BASF SE) Photopolymerization initiator 2: Omnirad 2959 (manufactured by IGM Resins B.V.) Photopolymerization initiator 3: compound having the following structure

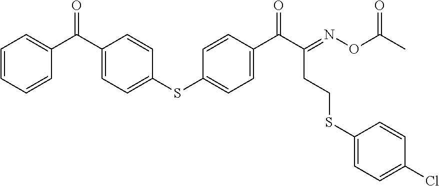 [SMILES: CC(=O)O/N=C(\CCSc1ccc(Cl)cc1)C(=O)c1ccc(Sc2ccc(C(=O)c3ccccc3)cc2)cc1]

Resin solution 1: 40% by mass PGMEA solution of a resin having the following structure (weight-average molecular weight: 11,000; a numerical value described together with a main chain is a molar ratio)

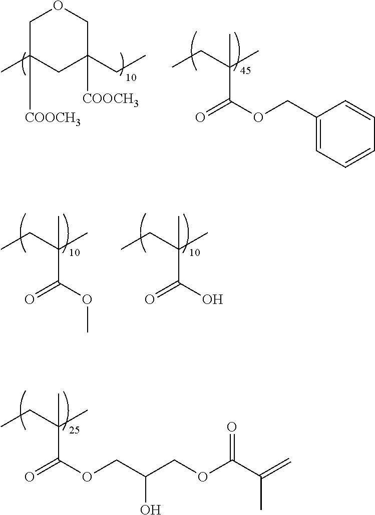

Polymerizable compound 1: compound having the following structure

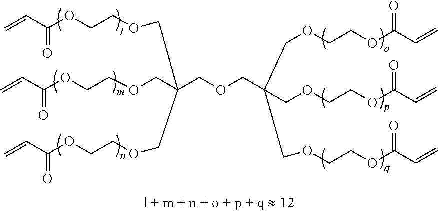

Polymerizable compound 2: compound having the following structure

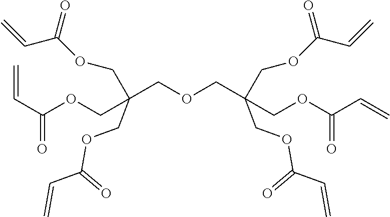 [SMILES: C=CC(=O)OCC(COCC(COC(=O)C=C)(COC(=O)C=C)COC(=O)C=C)(COC(=O)C=C)COC(=O)C=C]

Polymerizable compound 3: compound having the following structure

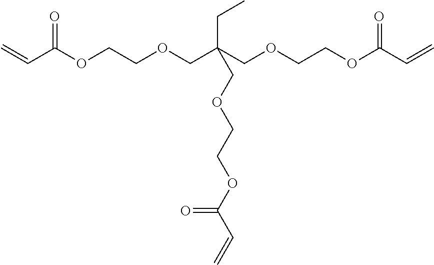 [SMILES: C=CC(=O)OCCOCC(CC)(COCCOC(=O)C=C)COCCOC(=O)C=C]

Epoxy compound 1: EHPE-3150 (manufactured by Daicel Corporation)
Surfactant 1: KF-6001 (manufactured by Shin-Etsu Chemical Co., Ltd., silicon-based surfactant)

### EXPLANATION OF REFERENCES

1: spherical silica
2: connection portion
11: support
12: partition wall
14: pixel
100: structural body

What is claimed is:

1. A composition comprising:
particles having a silanol group;
at least one generator selected from the group consisting of an acid generator and a base generator; and
a solvent,
wherein a content of the particles having a silanol group in a total solid content of the composition is 43% by mass or more.

2. The composition according to claim 1,
wherein a total content of the particles having a silanol group and the generator in the total solid content of the composition is 45% to 99% by mass.

3. The composition according to claim 1,
wherein the particles having a silanol group are silica particles.

4. The composition according to claim 3,
wherein the silica particles include at least one selected from the group consisting of silica particles having a shape in which a plurality of spherical silicas are connected in a bead shape, silica particles having a shape in which a plurality of spherical silicas are connected in a planar shape, and silica particles having a hollow structure.

5. The composition according to claim 1,
wherein the generator is an acid generator, and
the acid generator includes a photoacid generator.

6. The composition according to claim 5,
wherein a content of the photoacid generator in the total solid content of the composition is 1% to 10% by mass.

7. The composition according to claim 5,
wherein the photoacid generator includes at least one selected from the group consisting of an oxime sulfonate compound and a triazine compound.

8. The composition according to claim 1,
wherein the generator is a base generator, and
the base generator includes a photobase generator.

9. The composition according to claim 8,
wherein a content of the photobase generator in the total solid content of the composition is 1% to 10% by mass.

10. The composition according to claim 8,
wherein the photobase generator includes at least one selected from the group consisting of a carbamate compound and an acyl oxime compound.

11. The composition according to claim 1, further comprising:
a silanol compound having a molecular weight of 1,000 or less.

12. The composition according to claim 1, further comprising:
a surfactant.

13. The composition according to claim 1, further comprising:
a compound having an alkoxysilyl group.

14. The composition according to claim 1,
wherein a content of a resin in the total solid content of the composition is 30% by mass or less.

15. A cured film formed of the composition according to claim 1.

16. A structural body comprising:
a support;
a partition wall formed of the composition according to claim 1, which is provided on the support; and
a pixel provided in a region partitioned by the partition wall.

17. An optical filter comprising:
the cured film according to claim 15.

18. A solid-state imaging element comprising:
the cured film according to claim 15.

19. An image display device comprising:
the cured film according to claim 15.

20. A manufacturing method of a cured film, comprising:
a step of applying the composition according to claim 1 onto a support to form a composition layer; and
a step of subjecting the composition layer to a curing treatment,
wherein a cured film in which the composition layer is cured is obtained at a temperature of 150° C. or lower throughout all the steps, and
the step of subjecting the composition layer to a curing treatment includes a step of generating an acid or a base from an acid generator or a base generator contained in the composition layer by performing light irradiation or heating on the composition layer.
